(19) United States
(12) Patent Application Publication
(10) Pub. No.: US 2026/0160732 A1
(43) Pub. Date: Jun. 11, 2026

(54) ION SENSING WITH THREE-DIMENSIONAL VERTICAL DIFFERENTIAL INDUCTORS

(71) Applicant: Microchip Technology Inc., Chandler, AZ (US)

(72) Inventors: Mazhar Hoque, Gilbert, AZ (US); Arthur B. Eck, Gilbert, AZ (US); Amit Rai, Chandler, AZ (US); Samir Fuke, Tempe, AZ (US); Joseph Rascon, Chandler, AZ (US)

(73) Assignee: Microchip Technology Inc., Chandler, AZ (US)

(21) Appl. No.: 19/258,473

(22) Filed: Jul. 2, 2025

Related U.S. Application Data
(60) Provisional application No. 63/728,349, filed on Dec. 5, 2024.
(60) Provisional application No. 63/728,434, filed on Dec. 5, 2024.
(60) Provisional application No. 63/770,266, filed on Mar. 11, 2025.
(60) Provisional application No. 63/770,284, filed on Mar. 11, 2025.
(60) Provisional application No. 63/770,704, filed on Mar. 12, 2025.
(60) Provisional application No. 63/770,745, filed on Mar. 12, 2025.

(51) Int. Cl. G01N 27/74; H10D 1/00; H10D 1/20; H10D 1/62; H10D 80/20

(52) U.S. Cl. CPC G01N 27/74; H10D 1/045; H10D 1/20; H10D 1/62; H10D 80/215

(57) ABSTRACT

A device has a semiconductor chip comprising a substrate and an integrated circuit, a metal stack of metal layers connected to the semiconductor chip, and a planar spiral differential inductor comprising at least two metal layers of the metal stack, wherein the semiconductor chip defines a semiconductor plane having a semiconductor plane normal vector and the planar spiral differential inductor defines an inductor plane having an inductor plane normal vector, wherein an angle between the semiconductor plane normal vector and the inductor plane normal vector is between 1 and 90 degrees; a sensing membrane operable to become electrically charged when interacting with an ionized fluid, wherein the sensing membrane is operable to electrically communicate with the planar spiral differential inductor; and a fluid property measurement circuit operable to measure a quality factor or inductance of the planar spiral differential inductor and output a fluid property signal.

### RELATED PATENT APPLICATIONS

This application claims priority to commonly owned U.S. Provisional Patent Application Nos. 63/728,349 filed Dec. 5, 2024, 63/770,266 filed Mar. 28, 2025, 63/770,284 filed Mar. 11, 2025, 63/728,434 filed Dec. 5, 2024, 63/770,704 filed Mar. 12, 2025, and 63/770,745 filed Mar. 12, 2025, the entire contents of which are hereby incorporated by reference for all purposes.

### TECHNICAL FIELD

The present disclosure relates to ion sensing in fluids, in particular, ion sensing in fluid via vertically oriented differential inductors in CMOS metal stacks.

### BACKGROUND

Ion sensors can detect ion type/concentration of a fluid using ion sensing transistors, inductors, and capacitors. Acid/base balance or pH level (hydrogen ion concentration) in human bodies are critical for proper health. Human blood should have a pH in the range of 7.35-7.45. Human saliva should have a pH in the range of 6.2-7.6. Human sweat should have a pH in the range of 4.5-7. Human urine should have a pH in the range of 4.5-8. Changes in pH levels of these bodily fluids may indicate medical problems. A drop in pH can be a result of increased bodily production of acid or a loss of bicarbonate. A rise in pH can be caused by a loss of acid due to an increased rate of CO₂ excretion. Variations in pH outside normal range for a long time may cause damage to cells, tissues, and organs. Ion sensors may be used to detect virus, bacteria, or early-cancer, and analyze biochemical fluids and perform DNA sequencing. Ion sensors may be used in other applications such as agricultural (crops), industrial (food), mining, and environmental (water pollution).

Ion sensing transistors (ISFET) have previously comprised field effect transistors (FETs) with gate material removed to expose gate oxide directly to the fluid being tested to detect ions. Later, complementary metal oxide semiconductor (CMOS) technology has been used to sense ions in a fluid. A nitride passivation layer in standard CMOS technology acts as a pH/ion sensitive material. The top metal layer in a CMOS technology can be used as a sense plate, which modulates transistor characteristics based on type/concentration of ions in the fluid in contact with the passivation layer.

Inductors on silicon substrates may be used in an integrated circuit (IC). The most common type of inductor is a planar inductor. A planar inductor is a spiral pattern of metal conductors on the surface of the silicon substrate. The inductance of the inductor is determined by the number of turns, the area enclosed by the spiral, and the thickness of the metal layer. Increasing the inductance of the inductor requires increasing the footprint of the inductor on the silicon substrate.

Radio frequency circuits with power electronics, transformers, and inductors used for energy storage and filtering. Conventional approaches to create inductors use large silicon footprints when designing a LC tank or a Balun/transformer. Radio frequency (RF) circuits may use an LC tank or a voltage controlled oscillator (VCO).

There is a need for ion sensing devices in smaller silicon footprints.

### SUMMARY

According to an aspect, there is provided a device comprising: a semiconductor chip comprising a substrate and an integrated circuit; a metal stack comprising a plurality of metal layers, wherein the metal stack is connected to the semiconductor chip; and a first planar spiral differential inductor comprising at least two metal layers of the metal stack, wherein the semiconductor chip defines a semiconductor plane having a semiconductor plane normal vector and the first planar spiral differential inductor defines a first inductor plane having a first inductor plane normal vector, wherein an angle between the semiconductor plane normal vector and the first inductor plane normal vector is between 1 and 90 degrees; a sensing membrane operable to attract ions when interacting with an ionized fluid, wherein the sensing membrane is operable to electrically communicate with the first planar spiral differential inductor; and a fluid property measurement circuit operable to measure a quality factor or inductance of the first planar spiral differential inductor and output a fluid property signal.

An aspect as in the previous paragraph provides a device, wherein an angle between the semiconductor plane normal vector and the first inductor plane normal vector is 90 degrees.

An aspect as in one of the two previous paragraphs provides a device, comprising: a second planar spiral differential inductor comprising at least two metal layers of the metal stack.

An aspect as in one of the three previous paragraphs provides a device, wherein the first planar spiral differential inductor defines a first plane and second planar spiral differential inductor defines a second plane, wherein the first and second planes are substantially parallel.

An aspect as in one of the four previous paragraphs provides a device, wherein the first planar spiral differential inductor is a primary coil of a transformer and the second planar spiral differential inductor is a secondary coil of the transformer, wherein the fluid property measurement circuit is operable to measure a characteristic of the transformer and output a fluid property signal.

An aspect as in one of the five previous paragraphs provides a device, comprising a MOM capacitor formed in the metal stack and connected with the first planar spiral differential inductor, wherein the MOM capacitor and the first planar spiral differential inductor comprise an inductor capacitor tank.

An aspect as in one of the six previous paragraphs provides a device, wherein the fluid property measurement circuit is operable to measure a characteristic of the inductor capacitor tank and output a fluid property signal.

An aspect as in one of the seven previous paragraphs provides a device, wherein the sensing membrane is operable to be sensitive to any ion type or a specific ion type in the ionized fluid.

An aspect as in one of the eight previous paragraphs provides a device, wherein the MOM capacitor defines a MOM capacitor plane and the first planar spiral differential inductor defines a first inductor plane, wherein the MOM capacitor plane and the first planar spiral differential inductor plane are the same plane.

According to an aspect, there is provided a method, comprising: sensing an ionized fluid via a first sensing membrane interacting with a first planar spiral differential inductor; charging the first planar spiral differential inductor based on the sensing an ionized fluid, wherein the first planar spiral differential inductor comprises a planar spiral inductor comprising at least two metal layers of a metal stack connected to a semiconductor chip comprising a substrate and an integrated circuit, wherein the semiconductor chip defines a semiconductor plane having a semiconductor plane normal vector and the first planar spiral inductor defines a first inductor plane having a first inductor plane normal vector, wherein an angle between the semiconductor plane normal vector and the first inductor plane normal vector is between 1 and 90 degrees; measuring a change in quality factor or inductance of the first planar spiral differential inductor; and outputting a fluid property signal corresponding to the measured change in quality factor or inductance of the first planar spiral differential inductor.

An aspect as in the preceding paragraph provides a method, wherein sensing an ionized fluid via a sensing membrane comprises sensing a specific ion type.

An aspect as in one of the two previous paragraphs provides a method, comprising: insulating a second reference planar spiral inductor from the ionized fluid; measuring the quality factor or inductance of second reference planar spiral inductor; and comparing the measured quality factor or inductance of the second reference planar spiral inductor with the measured quality factor or inductance of the first spiral planar inductor.

An aspect as in one of the three previous paragraphs provides a method, wherein sensing an ionized fluid via a sensing membrane comprises sensing any ion type.

An aspect as in one of the four previous paragraphs provides a method, comprising: sensing an ionized fluid via a second sensing membrane interacting with a second planar spiral differential inductor; charging the second planar spiral differential inductor via the second sense electrode based on the sensing an ionized fluid, wherein the second planar spiral differential inductor comprises a planar spiral inductor in the metal stack; measuring a change in quality factor or inductance of the first and second planar spiral differential inductors; and outputting a fluid property signal corresponding to the measured change in quality factor or inductance of the first or second planar spiral differential inductors.

An aspect as in one of the five previous paragraphs provides a method, comprising: charging a MOM capacitor in the metal stack based on the sensing an ionized fluid, wherein the MOM capacitor and the first planar spiral differential inductor comprise an inductor capacitor tank; wherein measuring a change in quality factor or inductance of the first planar spiral differential inductor comprises measuring a change in a characteristic of the inductor capacitor tank; and outputting a fluid property signal corresponding to the measured change in the characteristic of the inductor capacitor tank.

According to an aspect, there is provided a fluid property sensor semiconductor device comprising a planar spiral differential inductor in a metal stack, and made by a process, the process comprising: forming a metal stack on a semiconductor chip, wherein the metal stack comprises a plurality of metal layers, wherein the semiconductor chip comprising a substrate and an integrated circuit; forming a first planar spiral differential inductor in the metal stack, wherein the first planar spiral differential inductor comprises at least two metal layers of the metal stack, wherein the semiconductor chip defines a semiconductor plane having a semiconductor plane normal vector and the first planar spiral differential inductor defines a first inductor plane having a first inductor plane normal vector, wherein an angle between the semiconductor plane normal vector and the first inductor plane normal vector is between 1 and 90 degrees; configuring a sensing membrane to electrically communicate with the first planar spiral differential inductor and configuring the sensing membrane to electrically interact when exposed to an ionized fluid; and configuring a fluid property measurement circuit to measure a quality factor or inductance of the first planar spiral differential inductor and output a fluid property signal.

An aspect as in the preceding paragraph provides a fluid property sensor semiconductor device comprising a planar spiral inductor in a metal stack, and made by a process, comprising: forming a second planar spiral differential inductor in the metal stack, wherein the second planar spiral differential inductor comprises at least two metal layers of the metal stack.

An aspect as in one of the two previous paragraphs provides a fluid property sensor semiconductor device comprising a planar spiral inductor in a metal stack, and made by a process, comprising forming a transformer in the metal stack, wherein the first planar spiral differential inductor is a primary coil of the transformer and the second planar spiral differential inductor is a secondary coil of the transformer.

An aspect as in one of the three previous paragraphs provides a fluid property sensor semiconductor device comprising a planar spiral inductor in a metal stack, and made by a process, comprising: insulating the second planar spiral differential inductor from the ionized fluid so the second planar spiral differential inductor is a reference inductor.

An aspect as in one of the four previous paragraphs provides a fluid property sensor semiconductor device comprising a planar spiral inductor in a metal stack, and made by a process, comprising: forming a MOM capacitor in the metal stack; connecting the first planar spiral differential inductor and the MOM capacitor; and forming a planar spiral inductor capacitor tank comprising the MOM capacitor and the first planar spiral differential inductor.

### BRIEF DESCRIPTION OF THE DRAWINGS

A more complete understanding of the disclosure and the advantages thereof may be acquired by referring to the following description, taken in conjunction with the accompanying drawings and wherein:

FIG. 1 shows a top view of a conventional inductor layout, wherein the coil lies in a horizontal plane of a complementary metal-oxide-semiconductor (CMOS) metal stack and is formed by a single or multiple layers of metal in the metal stack.

FIG. 2 shows a top view of an inductor with a planar spiral layout, wherein the coil lies in a vertical plane of a complementary metal-oxide-semiconductor (CMOS) metal stack and is formed by multiple layers of metal in the metal stack.

FIGS. 3A-3E show cross-sectional side views of a CMOS semiconductor chip during a front-end process of metallization, which connects semiconductor devices using metal lines and vias in metal layers of a metal stack.

FIGS. 4A-4C show a CMOS metalized semiconductor, wherein a front-end process of metallization has applied metal layers and via layers containing a planar spiral inductor, which form a metal stack applied to a semiconductor device and a fluid ion sensor on the metal stack.

FIG. 5 shows a perspective view of a vertically oriented high density three-dimensional inductor and a fluid ion sensor.

FIG. 6A shows a perspective view of two vertically oriented high density three-dimensional inductor windings, wherein the windings are laterally offset from one another and are connected in series and a fluid ion sensor.

FIG. 6B shows a perspective view of two vertically oriented high density three-dimensional inductor windings, wherein the windings are laterally offset from one another, one connected to a fluid ion sensor and the other being a reference inductor.

FIG. 7A shows a perspective view of an ion sensor with a plurality of vertically oriented high density three-dimensional inductor windings, wherein the windings are laterally offset from one another and are connected in series. FIG. 7B shows a schematic representation of the plurality of the vertically oriented high density three-dimensional inductor windings shown in FIG. 7A.

FIG. 8A shows a perspective view of an ion sensor with a plurality of vertically oriented high density three-dimensional inductor windings, wherein the windings are laterally offset from one another and are connected in series. FIG. 8B shows a schematic representation of the plurality of vertically oriented high density three-dimensional inductor windings shown in FIG. 8A.

FIG. 9A shows a perspective view of an ion sensor with seventeen vertically oriented high density three-dimensional inductor windings, wherein the windings are laterally offset from one another and are connected in series in a radial or coiled shape within a metal stack. FIG. 9B shows a schematic representation of the plurality of vertically oriented high density three-dimensional inductor windings shown in FIG. 9A.

FIGS. 10A and 10B show top and perspective views, respectively, of an ion sensor with a high density three-dimensional transformer/Balun, wherein a primary coil and a secondary coil are formed in the same metal and via layers of a CMOS metal stack.

FIGS. 11A and 11B show top and perspective views, respectively, of an ion sensor with a high density three-dimensional inductor capacitor (LC) tank.

FIGS. 12A and 12B show top and perspective views, respectively, of an ion sensor with a high density three-dimensional inductor capacitor (LC) tank, wherein the inductor and a MOM capacitor lie in the same vertical plane of a CMOS metal stack.

FIGS. 13A and 13B show top and perspective views, respectively, of an ion sensor with a high density three-dimensional inductor capacitor (LC) tank, wherein an inductor and a MOM capacitor lie in different vertically oriented planes of a CMOS metal stack.

FIG. 14A shows a front view of an ion sensor with a differential inductor in a metal stack. FIG. 14B shows a perspective view of the differential inductor shown in FIG. 14A.

FIGS. 15A-15E show an ion sensor with a CMOS metalized semiconductor, wherein a front-end process of metallization has applied metal layers and via layers, which form a differential inductor in a metal stack.

FIG. 16 shows a perspective view of an ion sensor with a differential inductor vertically oriented in a metal stack of a semiconductor package (not shown).

FIG. 17 shows a perspective view of an ion sensor with a differential inductor vertically oriented in a metal stack of a semiconductor package (not shown).

FIG. 18 shows a perspective view of an ion sensor with a differential inductor vertically oriented in a metal stack of a semiconductor package (not shown).

FIG. 19 shows a perspective view of an ion sensor with a differential inductor having a center tap and vertically oriented in a metal stack of a semiconductor package (not shown).

FIGS. 20A and 20B show top and perspective views, respectively, of an ion sensor with a high density three-dimensional differential inductor capacitor (LC) tank in a metal stack.

FIGS. 21A and 21B show top and perspective views, respectively, of an ion sensor with a high density three-dimensional differential inductor capacitor (LC) tank in a metal stack.

FIGS. 22A and 22B show top and perspective views, respectively, of an ion sensor with a vertically oriented inductor having a magnetic core through the center of the inductor.

FIG. 23A shows a perspective view of an ion sensor with a plurality of vertically oriented high density three-dimensional inductor windings with a magnetic core. FIG. 23B shows a schematic representation of the plurality of vertically oriented high density three-dimensional inductor windings and magnetic core shown in FIG. 23A.

FIG. 24A shows a perspective view of an ion sensor with seventeen vertically oriented high density three-dimensional inductor windings and a magnetic core. FIG. 24B shows a schematic representation of the plurality of vertically oriented high density three-dimensional inductor windings and magnetic core shown in FIG. 24A.

FIGS. 25A and 25B show top and perspective views, respectively, of an ion sensor with a high density three-dimensional transformer/Balun with a magnetic core.

FIGS. 26A and 26B show top and perspective views, respectively, of an ion sensor with a high density three-dimensional inductor capacitor (LC) tank having a magnetic core in the inductor.

FIGS. 27A and 27B show top and perspective views, respectively, of an ion sensor with a high density three-dimensional inductor capacitor (LC) tank and a magnetic core in the inductor.

The drawings accompanying and forming part of this specification are included to depict certain aspects of the disclosure. The reference number for any illustrated element that appears in multiple different figures has the same meaning across the multiple figures, and the mention or discussion herein of any illustrated element in the context of any particular figure also applies to each other figure, if any, in which that same illustrated element is shown. The features illustrated in the drawings are not necessarily drawn to scale. It should be noted that the features illustrated in the drawings are not necessarily drawn to scale.

### DESCRIPTION

According to aspects, there is provided ion sensors integrated with CMOS, which may be fabricated with a microcontroller and non-volatile memory on a single chip with additional capabilities. Aspects use three-dimensional differential inductors created with vertical stacking of the standard CMOS metal layers as a sensing device to detect the type and concentration of ions in a fluid. Such integrated ion sensing device with CMOS technology may allow them to be smaller, cheaper and portable, and also have the potential to be fabricated with microcontroller and non-volatile memory to include additional functionalities.

The differential inductor is formed in the CMOS metal stack, which is usually the top metal right below the nitride passivation layer, so as to interact with ions in a fluid in contact with the passivation layer. When exposed to a fluid with ions, the nitride layer acts as a sensing material and induces charge on the inductor to alter the inductance of the differential inductor according to the ion concentration in the fluid. The ions in a fluid may modulate the field of the three-dimensional differential inductors created with vertical windings. This may change the inductance and quality factor of the differential inductors. The ions in a fluid may modulate the charge on the differential inductor. Ions in the fluid may modulate the capacitance and quality factor of a MOSCAP. This may allow detections of the type and concentration of ions in the fluid.

A nitride passivation layer in standard CMOS technology may act as pH/ion sensitive material. The top metal layer may be used as a sense electrode, which modulates transistor characteristics based on type/concentration of ions in the fluid in contact with the passivation layer. Post processing can be used to deposit a specific sensing membrane to detect specific ions/gas.

The three-dimensional differential inductor may comprise a vertical planar spiral winding of the standard CMOS metal stacks above the substrate. The top-most metal may be used in the outermost track line of the differential inductor coil. When exposed to a fluid with ions, the nitride layer acts as a sensing material and modulates the field of the differential inductor through interaction with the top metal immediately underneath the nitride passivation layer. This may change the inductance and quality factor of the three-dimensional differential inductor and be used to indicate or identify the type and concentration of ions in the fluid.

According to aspects, the standard metal stacks may be used to create vertical windings of differential inductors instead of the conventional lateral winding. Vertically wound differential inductors may be used in RF circuits with LC tank or VCO (voltage controlled oscillator). Aspects use the availability of a large number of metal layers in advanced process technology nodes to create three-dimensional differential inductors with smaller footprints. Use of vertical winding allows the planar spiral differential inductor coil to be formed vertically, which may reduce the silicon area footprint.

The number of metal layers in the CMOS metal stacks has been increasing. The availability of ten or more metal layers in smaller technology nodes offers potential to create useful passive devices. Aspects use the availability of a large number of metal layers in advanced process technology nodes to create three-dimensional differential inductors with smaller footprints.

An individual turn or winding of the inductor may comprise a top metal segment, a bottom metal segment, and two via stacks, one at opposite ends, to connect the top and bottom metal segments. Subsequent inner turns or windings at the top may use one level lower than the previous top metal and one metal level higher than the previous bottom metal.

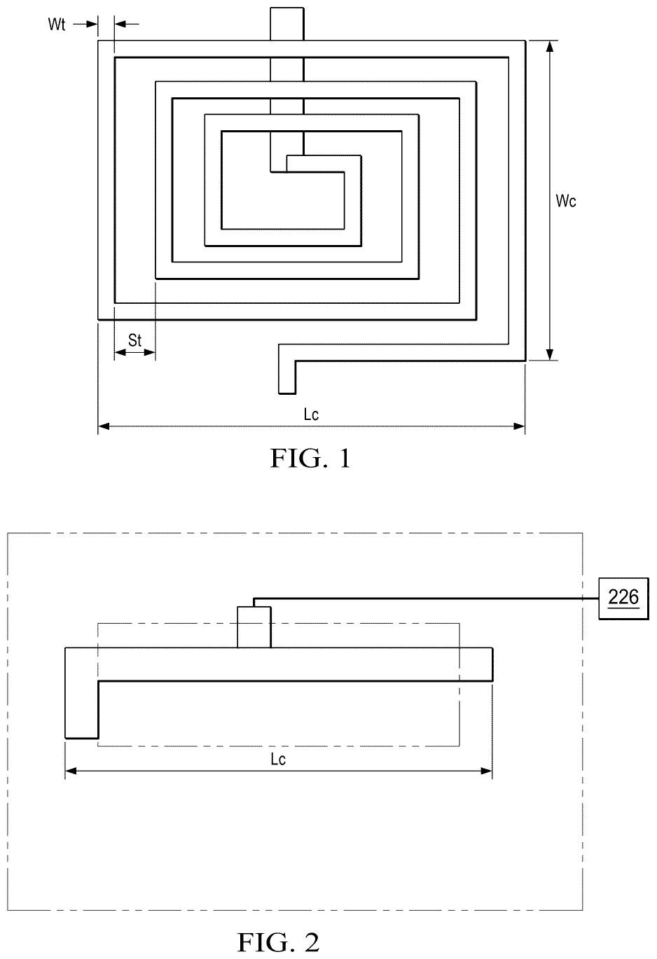

FIG. 1 shows a top view of a conventional inductor layout, wherein the coil lies in a horizontal plane of a complementary metal-oxide-semiconductor (CMOS) metal stack and is formed by a single or multiple layers of metal in the metal stack. As shown, this inductor winding has 3.5 turns. In this disclosure, the described semiconductors are assumed to be positioned in a horizonal or lateral plane. Metal layers and via layers, which form a metal stack on the semiconductor (not shown) are also assumed to be positioned in horizontal or lateral planes. The inductor shown in FIG. 1 lies completely in a single or multiple metal horizontal or lateral layer and is a lateral or horizontal planar spiral winding.

FIG. 2 shows a top view of an inductor with a planar spiral layout, wherein the coil lies in a vertical plane of a complementary metal-oxide-semiconductor (CMOS) metal stack and is formed by multiple layers of metal in the metal stack. This is a vertical winding. In this disclosure, the complimentary metal-oxide-semiconductor (CMOS) (not shown) devices are assumed to be positioned in a horizonal or lateral plane. The inductor shown in FIG. 2 (top view) is “vertically oriented” because it lies in a plane that has a vertical component relative to horizontally or laterally oriented complimentary metal-oxide-semiconductor (CMOS) devices. A fluid property measurement circuit 226 measures a quality factor or inductance of the planar spiral inductor and outputs a fluid property signal.

Vertically oriented inductors may be in a plane angled relative to the semiconductor device or chip positioned in a horizontal plane. For example, inductors with a planar spiral layout may be in a plane angled between 1 degree and 90 degrees relative to the semiconductor device positioned in a horizontal plane. In this disclosure, the term “vertically oriented” means angled between 1 degree and 90 degrees relative to a semiconductor device. The semiconductor chip defines a semiconductor plane having a semiconductor plane normal vector and the first inductor defines a first inductor plane having a first inductor plane normal vector. When vertically oriented, an angle between the semiconductor plane normal vector and the first inductor plane normal vector is between 1 and 90 degrees.

The width of the coil (Wc) may be limited by the number of metal layers for a single stack. Multiple coil stacks can be added in series or parallel. The coil thickness (Wt) may be limited by metal layer thickness. Multiple metal layers can be tied together in one track with sufficient via connections to increase coil thickness (Wt). The track spacing (St) may be limited by ILD (interlayer dielectric) thickness. Metal layer(s) can be skipped between subsequent track lines to increase track spacing (St). The number of coil turns may be limited by the number of metal layers for one coil stack. Multiple coil stacks can be added in series to increase inductance.

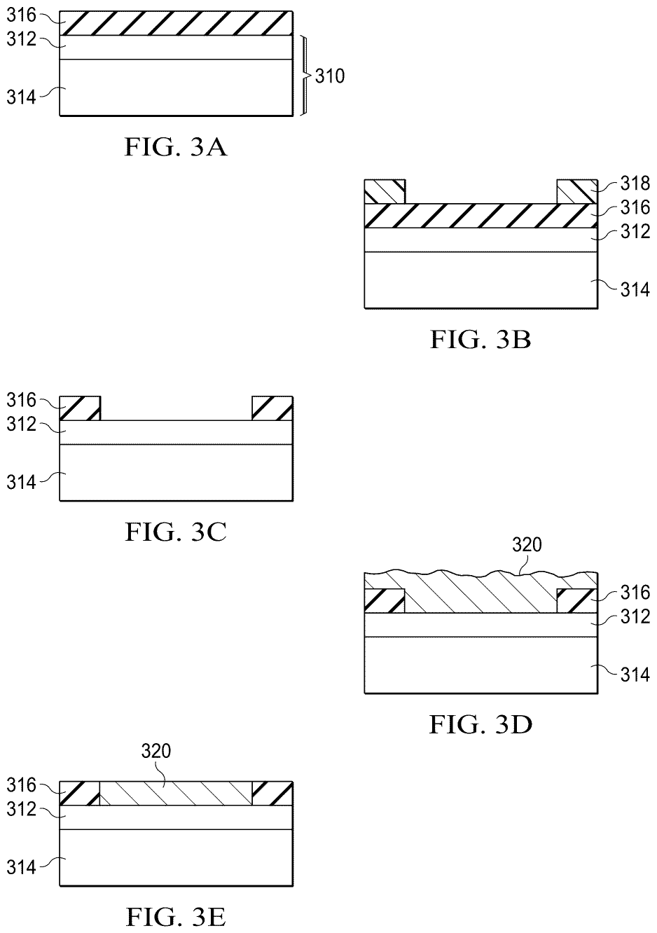

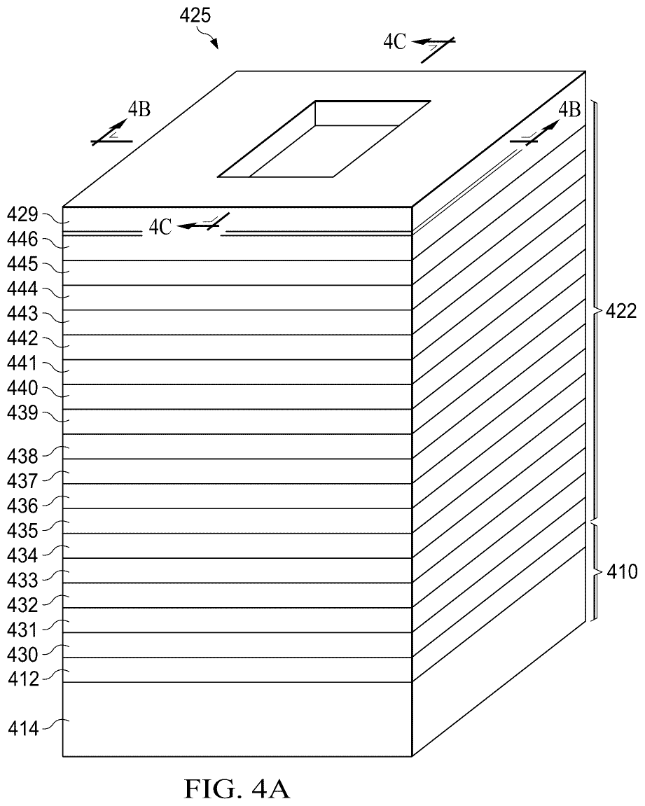

FIGS. 3A-3E show cross-sectional side views of a CMOS semiconductor chip during a front-end process of metallization, which connects semiconductor devices using metal lines and vias in metal layers of a metal stack. In particular, FIGS. 3A-3E show a damascene process for making copper “wires” on top of the circuit of a semiconductor device or chip. The manufacturing flow process starts with a semiconductor device 310 comprising transistors 312 built on a substrate 314. A dielectric 316 is deposited on the semiconductor device 310 as shown in FIG. 3A. As shown in FIG. 3B, a photo resist mask 318 is drawn in a pattern on the dielectric 316. As shown in FIG. 3C, the pattern drawing is etched to remove the exposed portions of the dielectric 316, and the photo resist mask 318 is removed. FIG. 3D shows a copper layer 320 deposited over the dielectric 316. As shown in FIG. 3E, the excess copper is removed via a chemical mechanical planarization (CMP) process that uses physical and chemical reactions to smooth and flatten the surfaces of the copper layer 320 and the dielectric 316. Aluminum “wires” may also be formed.

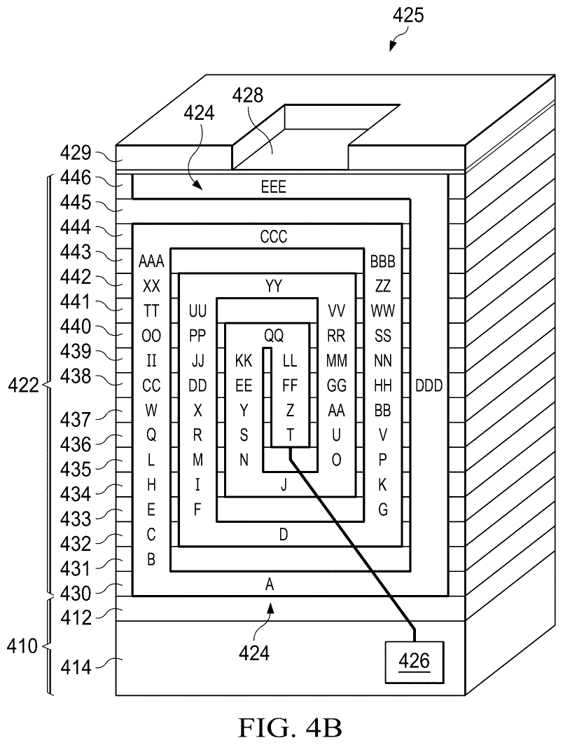

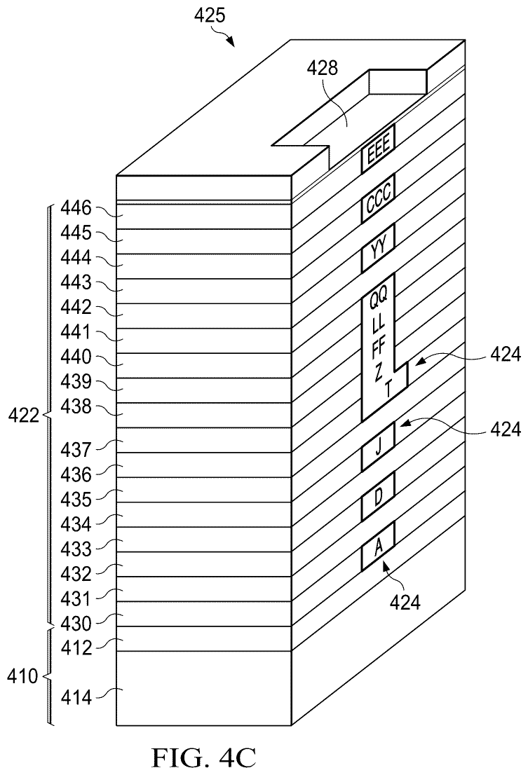

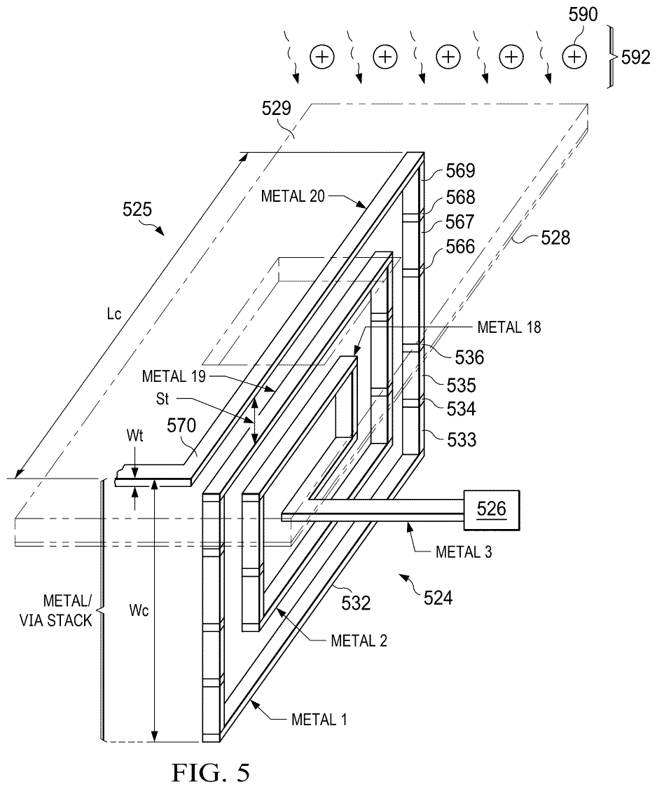

FIGS. 4A-4C show perspective views of a CMOS metalized semiconductor, wherein a front-end process of metallization has applied metal layers and via layers, which form a metal stack applied to a semiconductor device. FIG. 4A shows a perspective view of the CMOS semiconductor 410 having a metal stack 422. FIG. 4B shows a cross-sectional view of the CMOS metalized semiconductor taken at line B-B, shown in FIG. 4A. FIG. 4C shows a cross-sectional view of the CMOS metalized semiconductor taken at line C-C, shown in FIG. 4A. A metal layer 0 (M0) 430 is applied to the semiconductor device 410. A via layer 0 (V0) 431 is applied to the metal layer 0 (M0) 430. A metal layer 1 (M1) 432 is applied to the via layer 0 (V0) 431. A via layer 1 (V1) 433 is applied to the metal layer 1 (M1) 432. A metal layer 2 (M2) 434 is applied to the via layer 1 (V1) 433. A via layer 2 (V2) 435 is applied to the metal layer 2 (M2) 434. A metal layer 3 (M3) 436 is applied to the via layer 2 (V2) 435. A via layer 3 (V3) 437 is applied to the metal layer 3 (M3) 436. A metal layer 4 (M4) 438 is applied to the via layer 3 (V3) 437. A via layer 4 (V4) 439 is applied to the metal layer 4 (M4) 438. A metal layer 5 (M5) 440 is applied to the via layer 4 (V4) 439. A via layer 5 (V5) 441 is applied to the metal layer 5 (M5) 440. A metal layer 6 (M6) 442 is applied to the via layer 5 (V5) 441. A via layer 6 (V6) 443 is applied to the metal layer 6 (M6) 442. A metal layer 7 (M7) 444 is applied to the via layer 6 (V6) 443. A via layer 7 (V7) 445 is applied to the metal layer 7 (M7) 444. A metal layer 8 (M8) 446 is applied to the via layer 7 (V7) 445. Respective ones of the metal layers and the via layers are applied by a CMOS semiconductor front-end process of metallization similar to that discussed above with reference to FIGS. 3A-3E.

The sensor 425 has an inductor 424, a sensing membrane 428 (e.g., nitride passivation layer), and a sensor protective layer 429 (e.g., a polyimide layer). Ions in an ionized fluid proximate the sensing membrane modulates the field generated by the inductor, wherein the sensing membrane is operable to electrically communicate with the first planar spiral inductor 424. The ions in a fluid may modulate the charge on the inductor 424 through the sensing membrane 428. A fluid property measurement circuit 426 measures a quality factor or inductance of the planar spiral inductor and outputs a fluid property signal.

As shown in FIGS. 4B and 4C, the metal stack 422 has an inductor 424 formed across several layers of the metal stack 422. The metal 0 layer (M0) 430 has an inductor horizontal section A. The via 0 layer (V0) 431 has an inductor vertical section B and DDD. The metal 1 layer (M1) 432 has an inductor vertical sections C and DDD and an inductor horizontal section D. The via 1 layer (V1) 433 has inductor vertical sections E, F, G, and DDD. The metal 2 layer (M2) 434 has inductor vertical sections H, I, K, and DDD and an inductor horizontal section J. The via 2 layer (V2) 435 has inductor vertical sections L, M, N, O, P, and DDD. The metal 3 layer (M3) 436 has inductor vertical sections Q, R, S, T, U, V, and DDD. The via 3 layer (V3) 437 has inductor vertical sections W, X, Y, Z, AA, BB, and DDD. The metal 4 layer (M4) 438 has inductor vertical sections CC, DD, EE, FF, GG, HH, and DDD. The via 4 layer (V4) 439 has inductor vertical sections II, JJ, KK, LL, MM, NN, and DDD. The metal 5 layer (M5) 440 has inductor vertical sections OO, PP, RR, SS, and DDD, and inductor horizontal section QQ. The via 5 layer (V5) 441 has inductor vertical sections TT, UU, VV, WW, and DDD. The metal 6 layer (M6) 442 has inductor vertical sections XX, ZZ, and DDD, and inductor horizontal section YY. The via 6 layer (V6) 443 has inductor vertical sections AAA, BBB, and DDD. The metal 7 layer (M7) 444 has inductor vertical section DDD an inductor horizontal section CCC. The via 7 layer (V7) 445 has inductor vertical section DDD. The metal 8 layer (M8) 446 has inductor horizontal section EEE.

The inductor 424 formed across several layers of the metal stack 422 shown in FIGS. 4B and 4C is oriented to be positioned in a vertically oriented plane relative to the semiconductor device 410 with metal layers positioned in horizontal planes.

FIG. 5 shows a perspective view of a vertically oriented high density three-dimensional inductor 524. Horizontal portions of the winding are formed by metal 1 layer 532, metal 2 layer 534, metal 3 layer 536, metal 18 layer 566, metal 19 layer 568, and metal 20 layer 570. Vertical portions of the winding are formed by alternating sections of via 1 layer 533, metal 2 layer 534, via 2 layer 535, metal 3 layer 536, via and metal layers, metal 18 layer 566, via 18 layer 567, metal 19 layer 568, and via 19 layer 569. Winding thickness (Wt) may be limited by corresponding metal layer thickness. Multiple metal layers may be tied together with sufficient via connections to form one track to increase the winding thickness Wt. The track spacing St, which is the distance between windings, may be limited by interlayer dielectric ILD thickness. Metal layer(s) can be skipped between subsequent track lines to increase track spacing (St). The number of turns of an inductor coil or winding may be limited by the number of metal layers available in the metal stack. The winding width (Wc) may also be limited by the number of metal layers available in the metal stack. Both of these two limitations can be avoided by adding multiple coils in series to achieve higher inductance. The sensor 525 has an inductor 524, a sensing membrane 528 (e.g., nitride passivation layer), and a sensor protective layer 529 (e.g., a polyimide layer). Ions 590 in an ionized fluid 592 proximate the sensing membrane 528 modulate the field generated by the inductor 524, wherein the sensing membrane 528 is operable to electrically communicate with the planar spiral inductor 524. The ions 590 in a fluid 592 may modulate the charge on the inductor 524 through the sensing membrane 528. A fluid property measurement circuit 526 measures a quality factor or inductance of the planar spiral inductor 524 and outputs a fluid property signal.

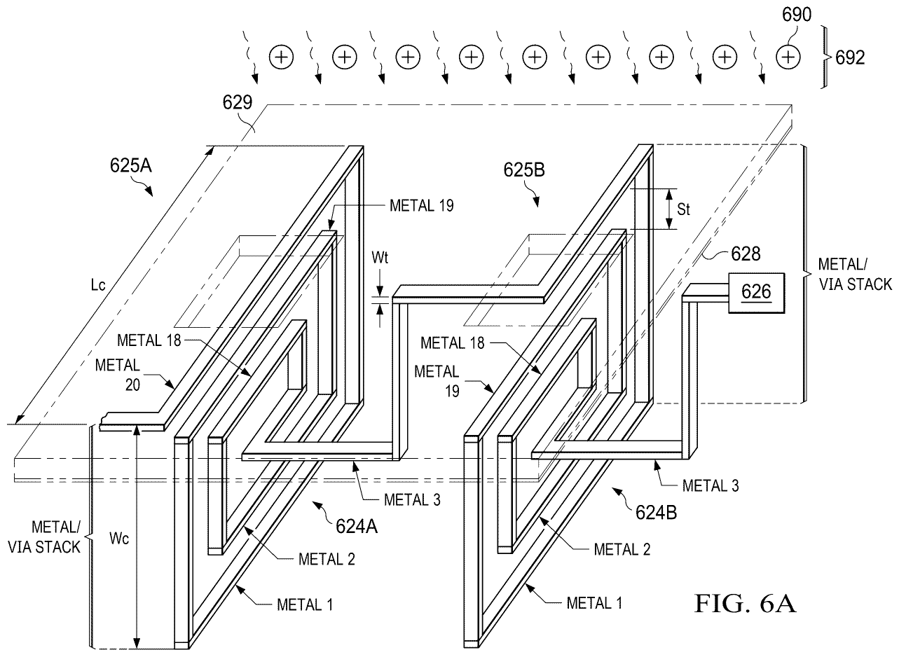

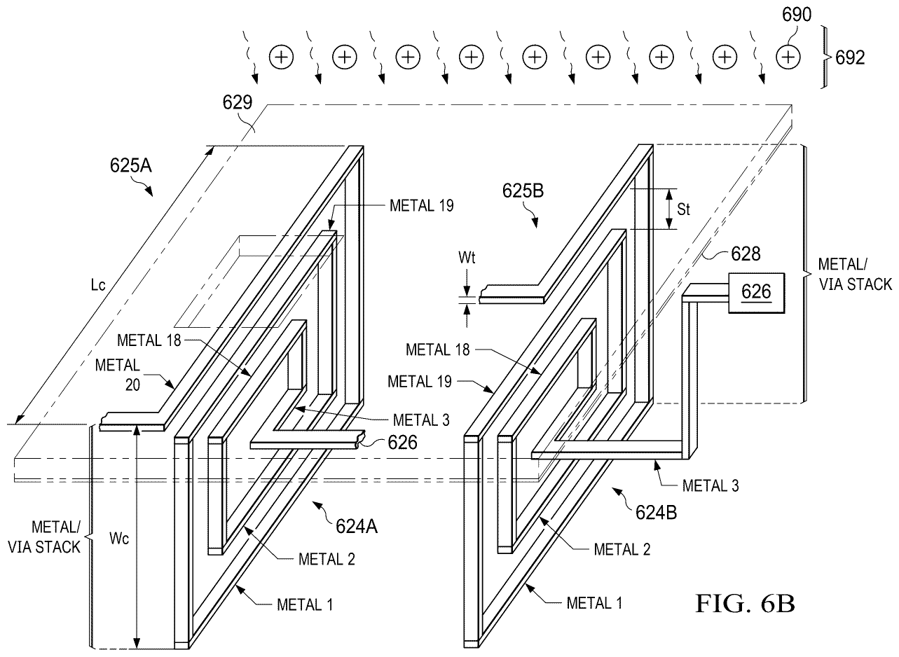

FIG. 6A shows a perspective view of two vertically oriented high density three-dimensional inductor windings 624A and 624B, wherein the windings are laterally offset from one another and are connected in series. Multiple coil stacks can be added in series or parallel for higher or lower inductance. The sensors 625A and 625B have inductors 624A and 624B, respectively, and a sensor protective layer 629 (e.g., a polyimide layer). The sensor 625A also has a window in the sensor protective layer 629 to expose a sensing membrane 628 (e.g., nitride passivation layer). Ions 690 in an ionized fluid 692 proximate the sensing membrane 628 modulate the field generated by the inductors 624A and 624B, wherein the sensing membrane 628 is operable to electrically communicate with the planar spiral inductors 624A and 624B. The ions 690 in a fluid 692 may modulate the charge on the inductors 624A and 624B through the sensing membrane 628. A fluid property measurement circuit 626 measures a quality factor or inductance of the planar spiral inductors 624A and 624B and outputs a fluid property signal.

FIG. 6B shows a perspective view of two vertically oriented high density three-dimensional inductor windings 624A and 624B, wherein the windings are laterally offset from one another. Multiple coil stacks can be added in series or parallel for greater inductance. Vertically oriented high density three-dimensional inductor winding 624B is a reference winding that is isolated from the ionized fluid 692 by the sensor protective layer 629. The sensor 625A has an inductor 624A, a sensing membrane 628 (e.g., nitride passivation layer), and a sensor protective layer 629 (e.g., a polyimide layer). Ions 690 in an ionized fluid 692 proximate the sensing membrane 628 modulate the field generated by the inductor, wherein the sensing membrane is operable to electrically communicate with the planar spiral inductor 624A. The ions 690 in a fluid 692 may modulate the charge on the inductor 624A through the sensing membrane 628. A fluid property measurement circuit 626 measures a quality factor or inductance of the planar spiral inductors 624A and 624B and outputs a fluid property signal and a reference signal and then compares the signals.

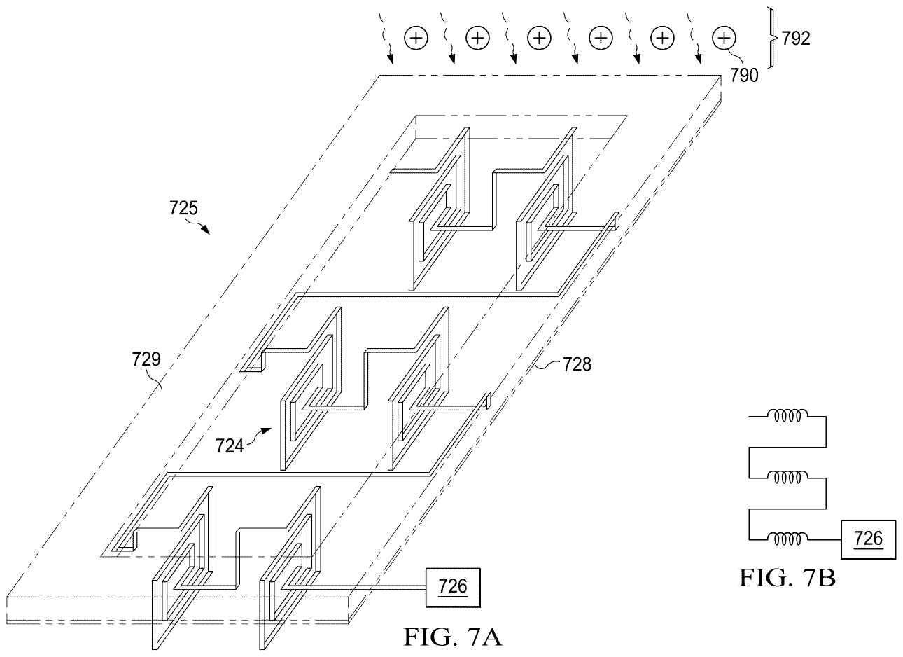

FIG. 7A shows a perspective view of a plurality of vertically oriented high density three-dimensional inductor windings, wherein the windings are laterally offset from one another and are connected in series. In this example, six vertically oriented high density three-dimensional inductor windings are connected in series. The six inductor windings are oriented in the same or parallel planes. FIG. 7B shows a schematic representation of the plurality of the vertically oriented high density three-dimensional inductor windings shown in FIG. 7A. The sensor 725 has an inductor 724, a sensing membrane 728 (e.g., nitride passivation layer), and a sensor protective layer 729 (e.g., a polyimide layer). Ions 790 in an ionized fluid 792 proximate the sensing membrane 728 modulate the field generated by the inductor. A fluid property measurement circuit 726 measures a quality factor or inductance of the planar spiral inductors 724 and outputs a fluid property signal.

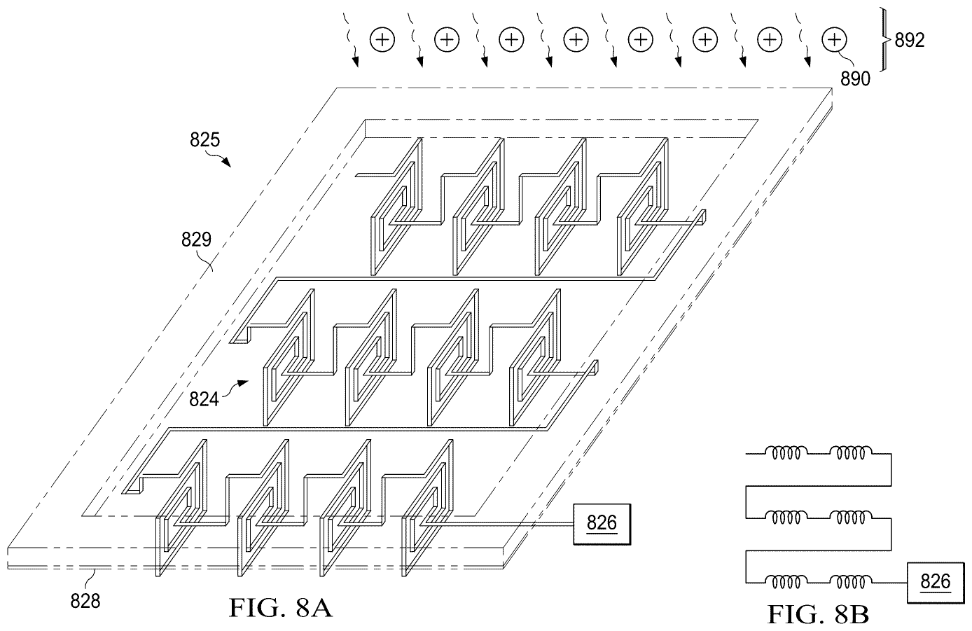

FIG. 8A shows a perspective view of a plurality of vertically oriented high density three-dimensional inductor windings, wherein the windings are laterally offset from one another and are connected in series. In this example, twelve vertically oriented high density three-dimensional inductor windings are connected in series. The twelve inductor windings are oriented in the same or parallel planes. FIG. 8B shows a schematic representation of the plurality of vertically oriented high density three-dimensional inductor windings shown in FIG. 8A. The sensor 825 has an inductor 824, a sensing membrane 828 (e.g., nitride passivation layer), and a sensor protective layer 829 (e.g., a polyimide layer). Ions 890 in an ionized fluid 892 proximate the sensing membrane 828 modulate the field generated by the inductor. A fluid property measurement circuit 826 measures a quality factor or inductance of the planar spiral inductors 824 and outputs a fluid property signal.

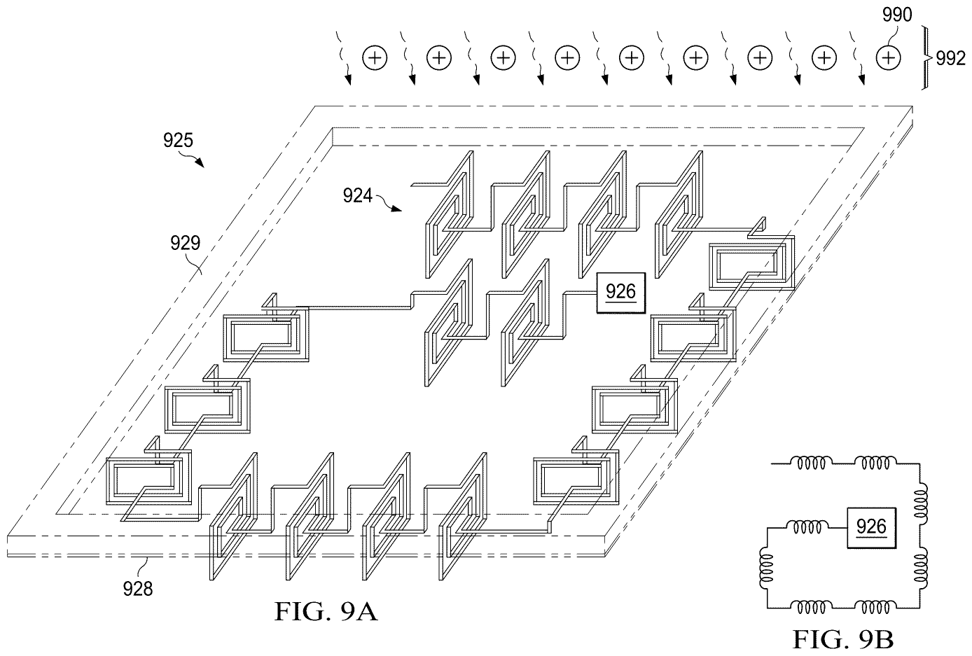

FIG. 9A shows a perspective view of seventeen vertically oriented high density three-dimensional inductor windings, wherein the windings are laterally offset from one another and are connected in series in a radial or coiled shape within a metal stack. In this example, seventeen vertically oriented high density three-dimensional inductor windings are connected in series. Some of the seventeen inductor windings are oriented in the same or parallel planes and others of the seventeen inductor windings are oriented in nonparallel planes. FIG. 9B shows a schematic representation of the plurality of vertically oriented high density three-dimensional inductor windings shown in FIG. 9A. The sensor 925 has an inductor 924, a sensing membrane 928 (e.g., nitride passivation layer), and a sensor protective layer 929 (e.g., a polyimide layer). Ions 990 in an ionized fluid 992 proximate the sensing membrane 928 modulate the field generated by the inductor. A fluid property measurement circuit 926 measures a quality factor or inductance of the planar spiral inductors 924 and outputs a fluid property signal.

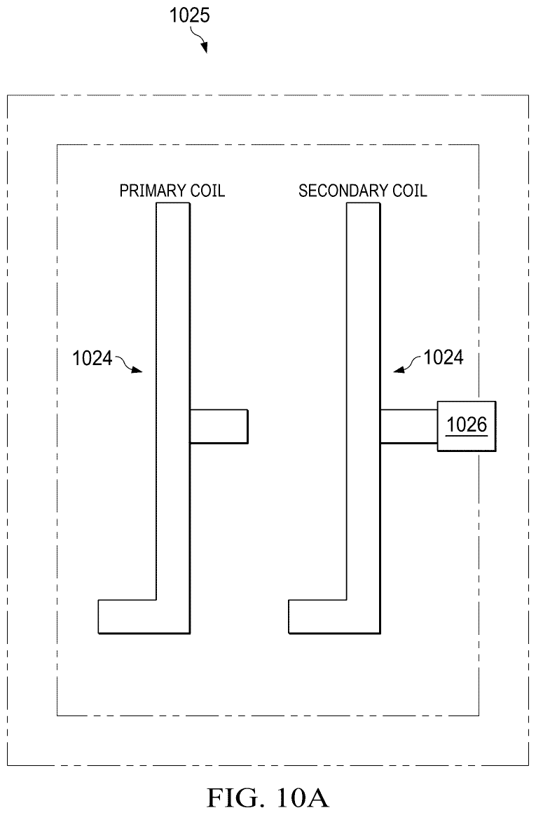

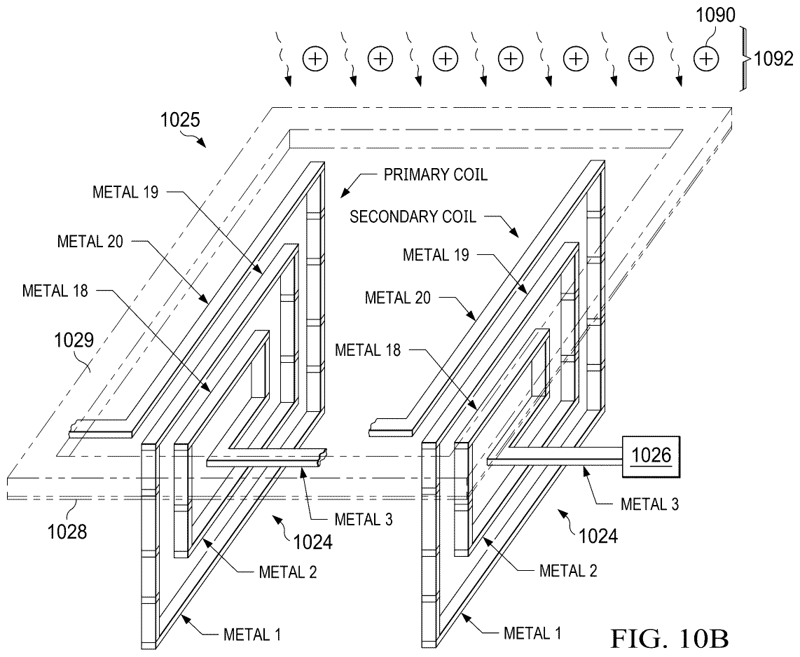

FIGS. 10A and 10B show top and perspective views, respectively, of a high density three-dimensional transformer/Balun, wherein a primary coil and a secondary coil are formed in the same metal and via layers of a CMOS metal stack and are offset laterally from one another. The primary and secondary coils are vertically oriented in a complementary metal-oxide-semiconductor (CMOS) metal stack and are formed by multiple layers of metal in the metal stack. These are vertically oriented windings. The sensor 1025 has an inductor 1024, a sensing membrane 1028 (e.g., nitride passivation layer), and a sensor protective layer 1029 (e.g., a polyimide layer). Ions 1090 in an ionized fluid 1092 proximate the sensing membrane 1028 modulate the field generated by the inductor 1024. A fluid property measurement circuit 1026 measures a quality factor or inductance of the planar spiral inductors 1024 and outputs a fluid property signal.

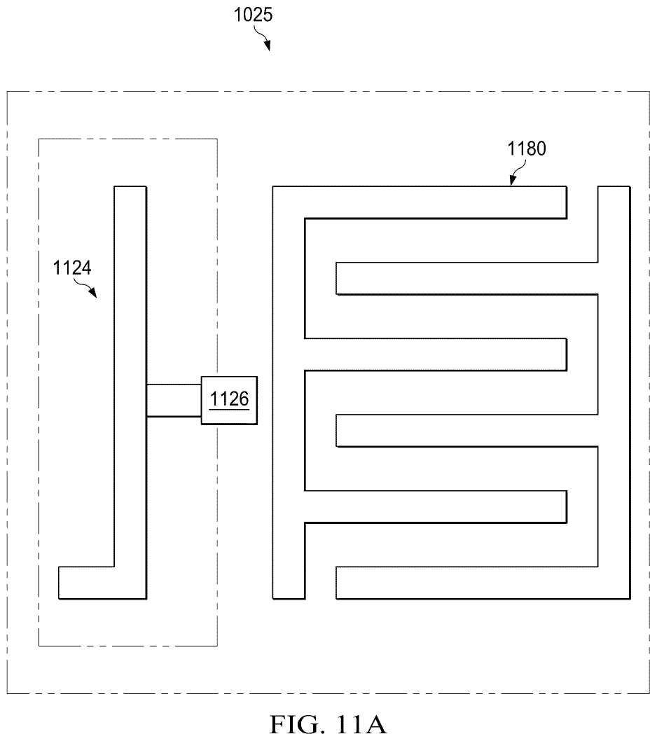

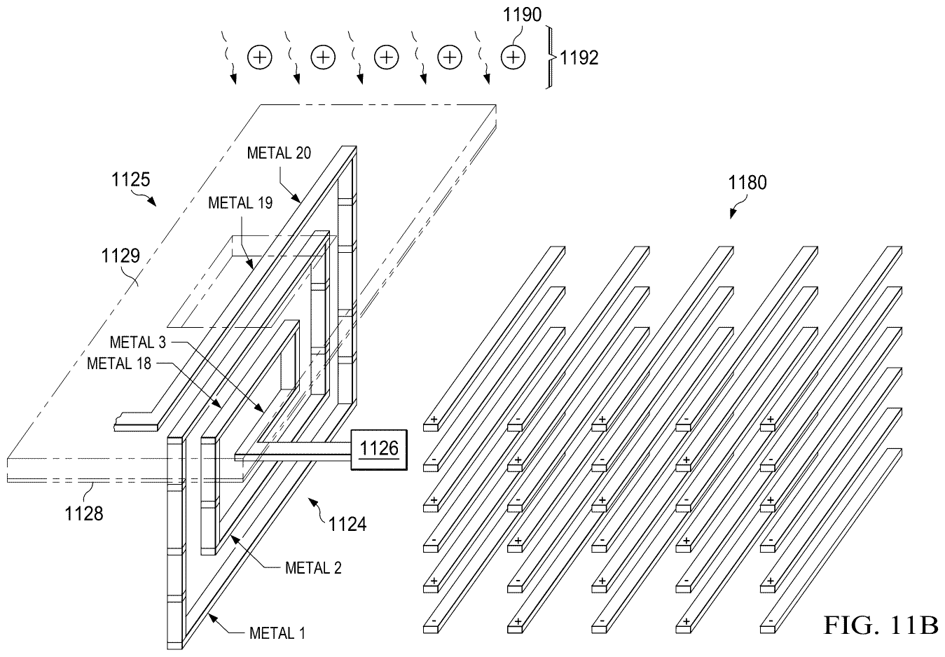

FIGS. 11A and 11B show top and perspective views, respectively, of a high density three-dimensional inductor capacitor (LC) tank. The inductor 1124 lies in a vertical plane of a complementary metal-oxide-semiconductor (CMOS) metal stack and is formed by multiple layers of metal in the metal stack. The MOM capacitor 1180 is three-dimensional and lies in the same complementary metal-oxide-semiconductor (CMOS) metal stack and is formed by multiple layers of metal in the metal stack. The inductor 1124 and the MOM capacitor 1180 are formed in the same metal layers of the CMOS metal stack and are offset laterally from one another. The sensor 1125 has an inductor 1124, a sensing membrane 1128 (e.g., nitride passivation layer), and a sensor protective layer 1129 (e.g., a polyimide layer). Ions 1190 in an ionized fluid 1192 proximate the sensing membrane 1128 modulates the field generated by the inductor. A fluid property measurement circuit 1126 measures a quality factor or inductance of the planar spiral inductor 1124 and outputs a fluid property signal.

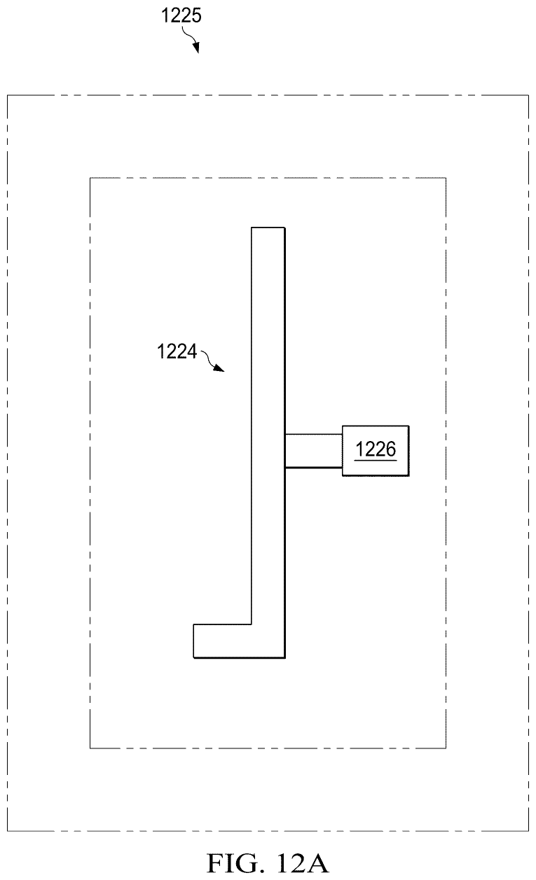

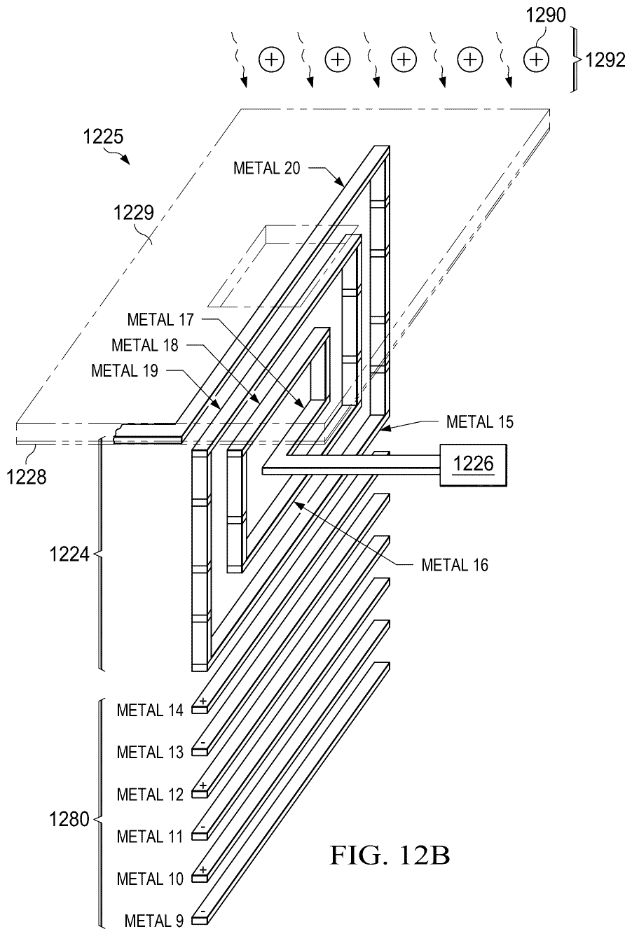

FIGS. 12A and 12B show top and perspective views, respectively, of a high density three-dimensional inductor capacitor (LC) tank of the present disclosure, wherein the inductor 1224 and a MOM capacitor 1280 lie in the same vertical plane of a complementary metal-oxide-semiconductor (CMOS) metal stack and are formed by multiple layers of metal in the metal stack. These are vertical components. The MOM capacitor 1280 is formed in metal layers 9 through 14 of the metal stack and the inductor 1224 is formed in metal layers 15 through 20 of the same metal stack directly above the MOM capacitor 1280 in the same vertically oriented plane. The inductor 1224 may be built with top metals and the MOM capacitor 1280 may be built with bottom metals below a single metal line (or vice versa). The sensor 1225 has an inductor 1224, a sensing membrane 1228 (e.g., nitride passivation layer), and a sensor protective layer 1229 (e.g., a polyimide layer). Ions 1290 in an ionized fluid 1292 proximate the sensing membrane 1228 modulate the field generated by the inductor. A fluid property measurement circuit 1226 measures a quality factor or inductance of the planar spiral inductors 1224 and outputs a fluid property signal.

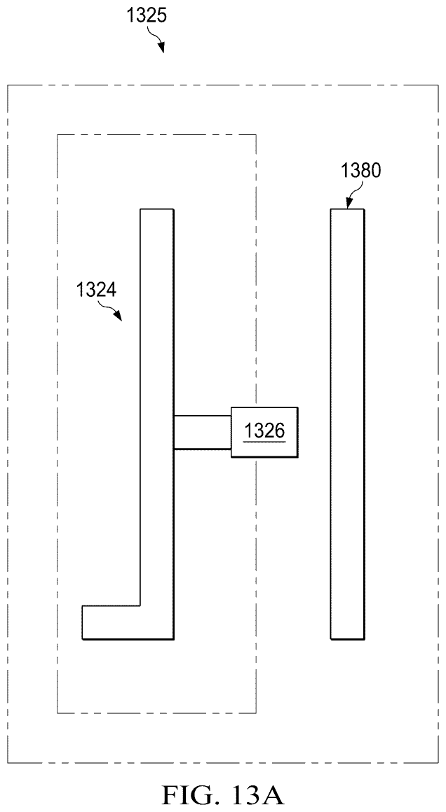

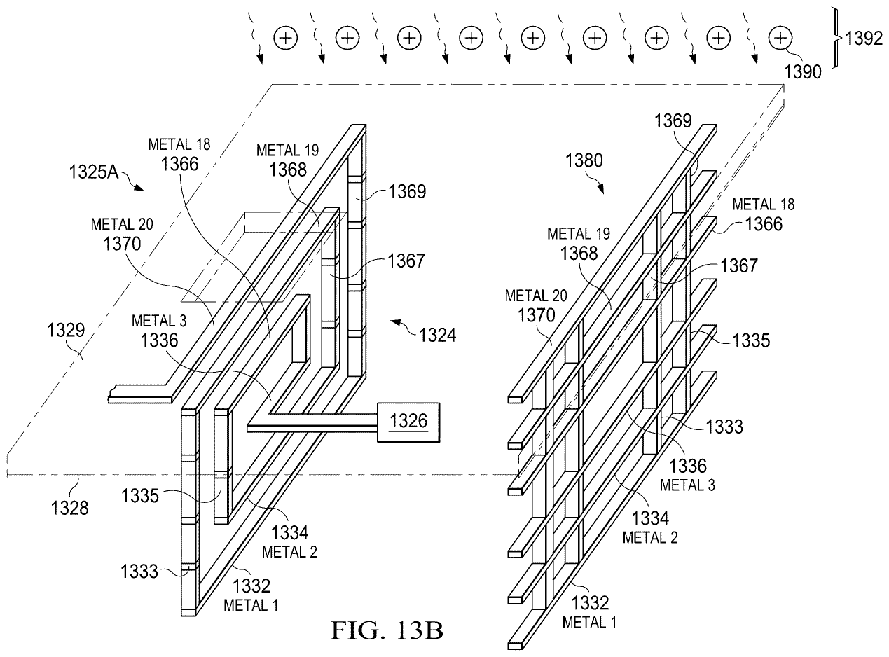

FIGS. 13A and 13B show top and perspective views, respectively, of a high density three-dimensional inductor capacitor (LC) tank. The inductor 1324 and a MOM capacitor 1380 lie in different vertically oriented planes of a complementary metal-oxide-semiconductor (CMOS) metal stack and are formed by multiple layers of metal in the metal stack. These are vertically oriented components. The inductor 1324 and MOM capacitor 1380 are formed in the same metal layers but are positioned laterally offset from one another. Horizontal portions of the inductor 1324 winding are formed by metal 1 layer 1332, metal 2 layer 1334, metal 3 layer 1336, metal 18 layer 1366, metal 19 layer 1368, and metal 20 layer 1370. Vertical portions of the winding are formed by alternating sections of via 1 layer 1333, metal 2 layer 1334, via 2 layer 1335, metal 3 layer 1336, via and metal layers, metal 18 layer 1366, via 18 layer 1367, metal 19 layer 1368, and via 19 layer 1369. Horizontal portions of the MOM capacitor 1380 are formed by metal 1 layer 1332, metal 2 layer 1334, metal 3 layer 1336, via and metal layers, metal 18 layer 1366, metal 19 layer 1368, and metal 20 layer 1370. The sensor 1325 has an inductor 1324, a sensing membrane 1328 (e.g., nitride passivation layer), and a sensor protective layer 1329 (e.g., a polyimide layer). Ions 1390 in an ionized fluid 1392 proximate the sensing membrane 1328 modulate the field generated by the inductor. A fluid property measurement circuit 1326 measures a quality factor or inductance of the planar spiral inductors 1324 and outputs a fluid property signal.

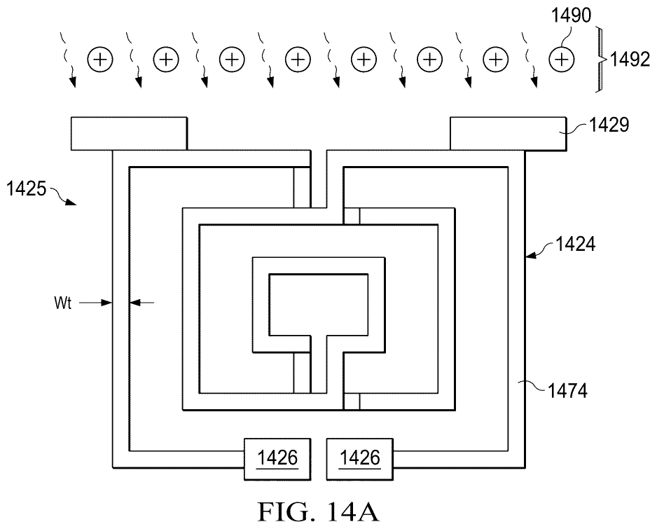

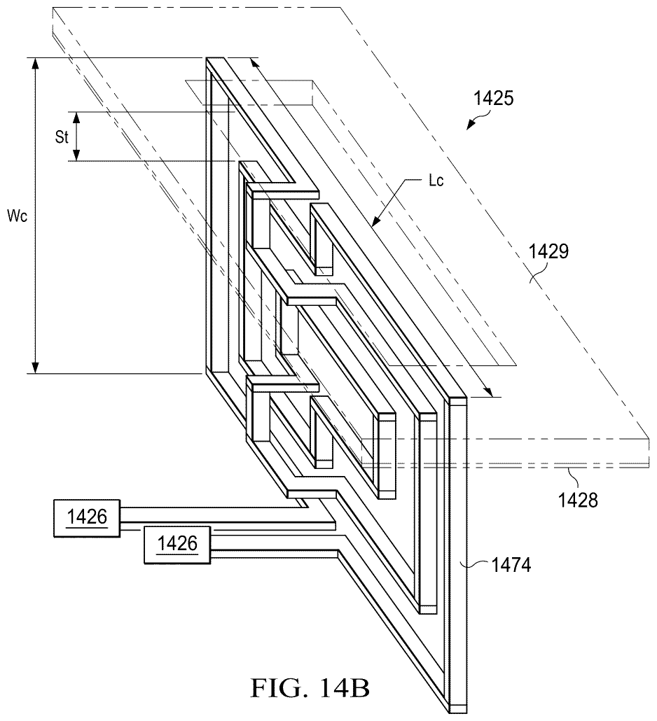

FIG. 14A shows a front view of a differential inductor in a metal stack. FIG. 14B shows a perspective view of the differential inductor shown in FIG. 14A. Wt may be limited by corresponding metal thickness. Multiple metal layers can be tied together with sufficient via connections to form one track to increase Wt. St may be limited by ILD thickness. Metal layer(s) can be skipped between subsequent track lines to increase track spacing St. The two ends of the differential inductor may be at the bottom metal layer as well. The sensor 1425 has an inductor 1424, a sensing membrane 1428, and a sensor protective layer 1429 (e.g., a polyimide layer). Ions 1490 in an ionized fluid 1492 proximate the sensing membrane 1428 modulate the field generated by the inductor. A fluid property measurement circuit 1426 measures a quality factor or inductance of the planar spiral inductor 1424 and outputs a fluid property signal.

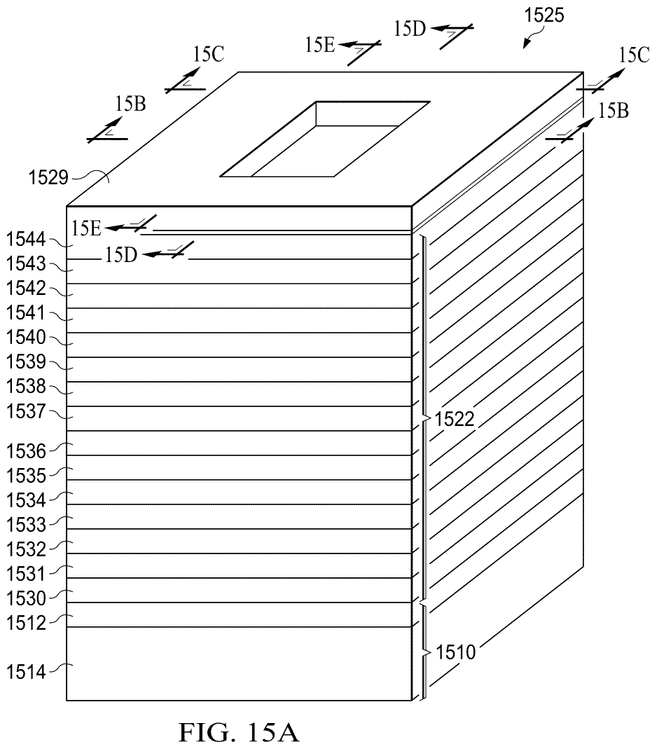

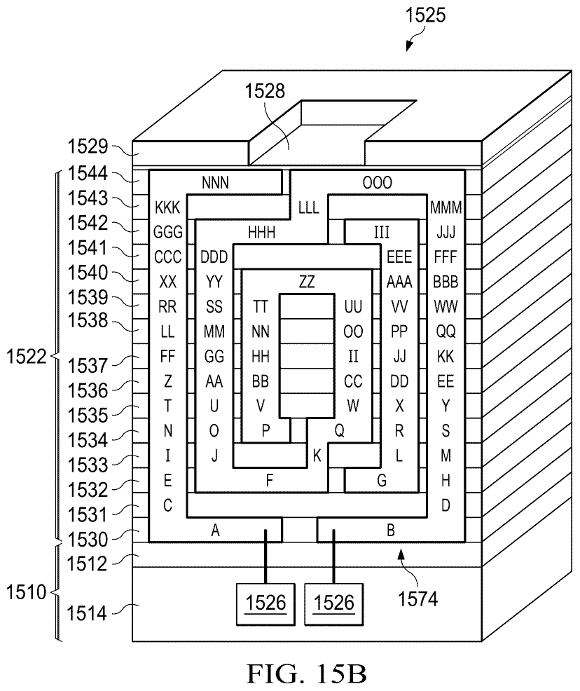

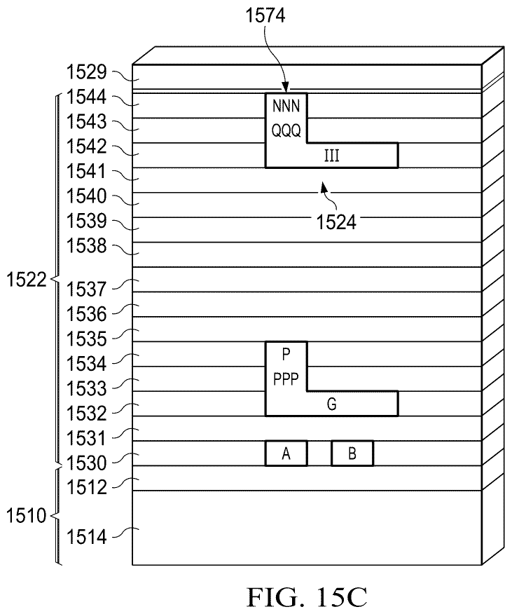

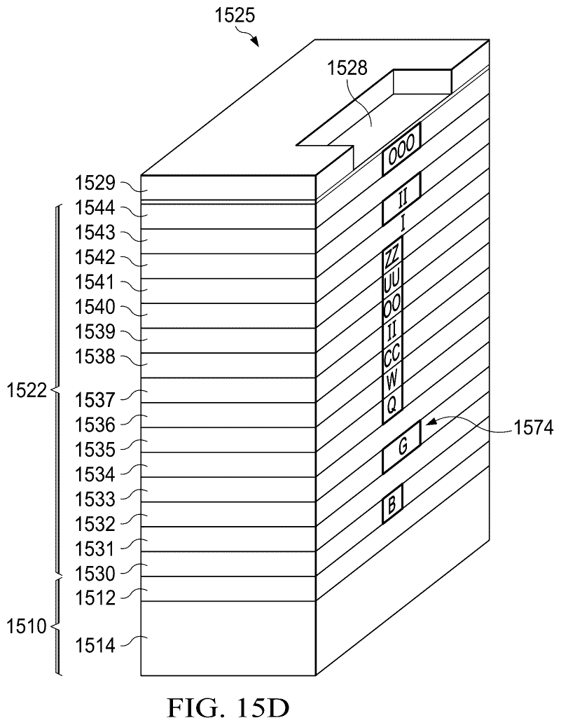

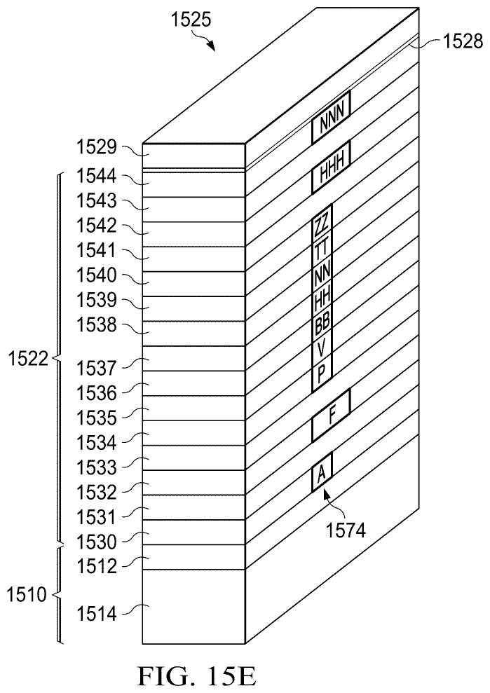

FIGS. 15A-15E show a CMOS metalized semiconductor, wherein a front-end process of metallization has applied metal layers and via layers, which form a metal stack applied to a semiconductor device. FIG. 15A shows a perspective view of the CMOS semiconductor 1510 having a metal stack 1522. FIG. 15B shows a cross-sectional view of the CMOS metalized semiconductor taken at line B-B, shown in FIG. 15A. FIG. 15C shows a cross-sectional view of the CMOS metalized semiconductor taken at line C-C, shown in FIG. 15A. A metal layer 0 (M0) 1530 is applied to the semiconductor device 1510. A via layer 0 (V0) 1531 is applied to the metal layer 0 (M0) 1530. A metal layer 1 (M1) 1532 is applied to the via layer 0 (V0) 1531. A via layer 1 (V1) 1533 is applied to the metal layer 1 (M1) 1532. A metal layer 2 (M2) 1534 is applied to the via layer 1 (V1) 1533. A via layer 2 (V2) 1535 is applied to the metal layer 2 (M2) 1534. A metal layer 3 (M3) 1536 is applied to the via layer 2 (V2) 1535. A via layer 3 (V3) 1537 is applied to the metal layer 3 (M3) 1536. A metal layer 4 (M4) 1538 is applied to the via layer 3 (V3) 1537. A via layer 4 (V4) 1539 is applied to the metal layer 4 (M4) 1538. A metal layer 5 (M5) 1540 is applied to the via layer 4 (V4) 1539. A via layer 5 (V5) 1541 is applied to the metal layer 5 (M5) 1540. A metal layer 6 (M6) 1542 is applied to the via layer 5 (V5) 1541. A via layer 6 (V6) 1543 is applied to the metal layer 6 (M6) 1542. A metal layer 7 (M7) 1544 is applied to the via layer 6 (V6) 1543. Respective ones of the metal layers and the via layers are applied by a CMOS semiconductor front-end process of metallization similar to that discussed above with reference to FIGS. 3A-3E.

As shown in FIGS. 15B-15D , the metal stack 1522 has a differential inductor 1574 formed across several layers of the metal stack 1522. The metal 0 layer (M0) 1530 has inductor horizontal sections A and B. The via 0 layer (V0) 1531 has differential inductor vertical sections C and D. The metal 1 layer (M1) 1532 has differential inductor vertical sections E and H and differential inductor horizontal sections F and G. The via 1 layer (V1) 1533 has inductor vertical sections I, J, K, L, M, and PPP. The metal 2 layer (M2) 1534 has inductor vertical sections N, O, R, and S and differential inductor horizontal sections P and Q. The via 2 layer (V2) 1535 has differential inductor vertical sections T, U, V, W, X, and Y. The metal 3 layer (M3) 1536 has inductor vertical sections Z, AA, BB, CC, DD, and EE. The via 3 layer (V3) 1537 has inductor vertical sections FF, GG, HH, II, JJ, and KK. The metal 4 layer (M4) 1538 has differential inductor vertical sections LL, MM, NN, OO, PP, and QQ. The via 4 layer (V4) 1539 has differential inductor vertical sections RR, SS, TT, UU, VV, and WW. The metal 5 layer (M5) 1540 has differential inductor vertical sections XX, YY, AAA, and BBB, and differential inductor horizontal section ZZ. The via 5 layer (V5) 1541 has differential inductor vertical sections CCC, DDD, EEE, and FFF. The metal 6 layer (M6) 1542 has differential inductor vertical sections GGG and JJJ, and differential inductor horizontal sections HHH and III. The via 6 layer (V6) 1543 has differential inductor vertical sections KKK, LLL, MMM, and QQQ. The metal 7 layer (M7) 1544 has a differential inductor horizontal sections NNN and OOO.

The differential inductor 1574 formed across several layers of the metal stack 1522 shown in FIGS. 15B-15E is oriented to be positioned in a vertically oriented plane relative to the semiconductor device 1510 positioned in a horizontally oriented plane. FIG. 15C shows cross-over elements of the differential inductor 1574.

The sensor 1525 has an inductor 1524, a sensing membrane 1528 (e.g., nitride passivation layer), and a sensor protective layer 1529 (e.g., a polyimide layer). Ions in an ionized fluid proximate the sensing membrane modulate the field generated by the inductor, wherein the sensing membrane is operable to electrically communicate with the differential inductor 1574. The ions in a fluid may modulate the charge on the differential inductor 1574 through the sensing membrane 1528. A fluid property measurement circuit 1526 measures a quality factor or inductance of the differential inductor 1574 and outputs a fluid property signal.

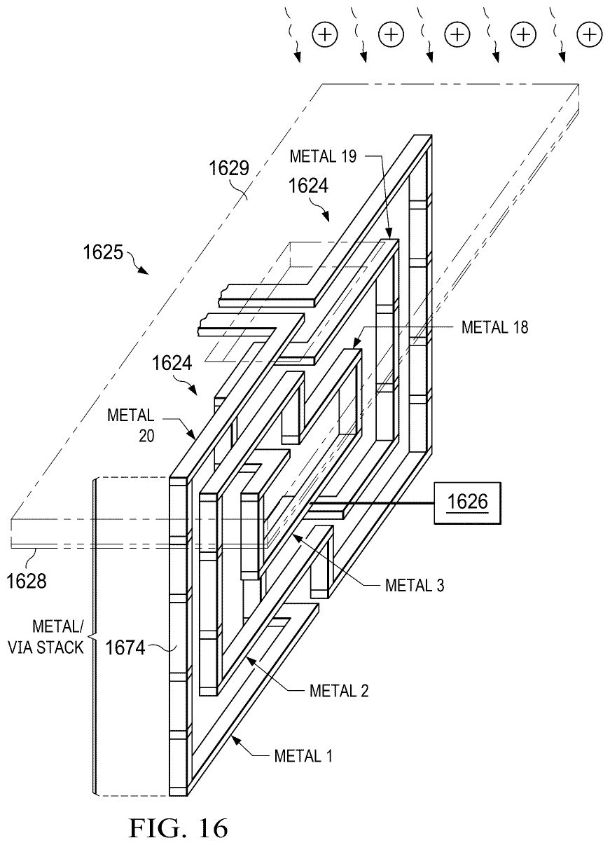

FIG. 16 shows a perspective view of a differential inductor vertically oriented in a metal stack of a semiconductor package (not shown). This design has offset horizontal sections in metal 2 layer (M2) and metal 19 layer (M19). A vertical section connects the offset horizontal section in metal 2 layer (M2) to an L-shaped horizontal section in metal 1 layer (M1). Another vertical section connects the offset horizontal section in metal 19 layer (M19) to an L-shaped horizontal section in metal 18 layer (M18). The sensor 1625 has an inductor 1624, a sensing membrane 1628 (e.g., nitride passivation layer), and a sensor protective layer 1629 (e.g., a polyimide layer). The ions in a fluid may modulate the charge on the differential inductor 1674 through the sensing membrane 1628. A fluid property measurement circuit 1626 measures a quality factor or inductance of the differential inductor 1674 and outputs a fluid property signal.

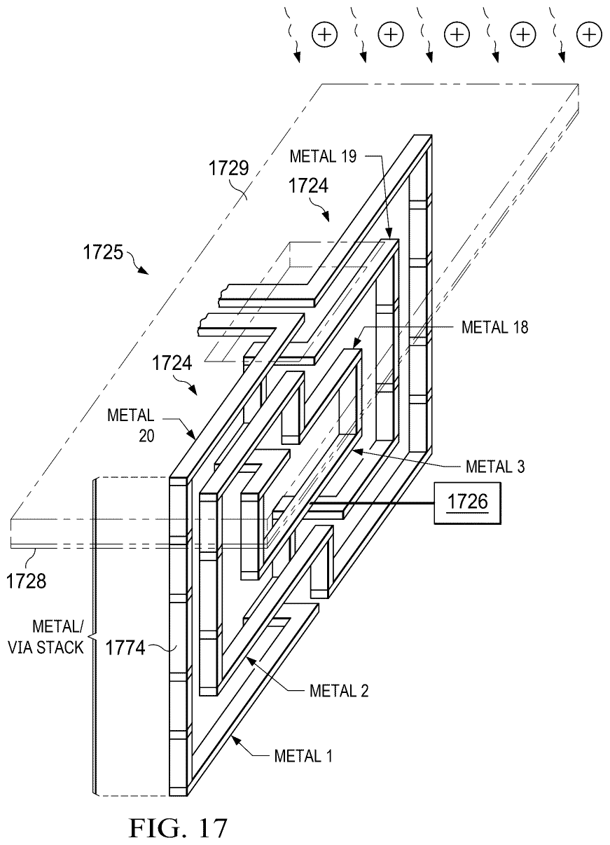

FIG. 17 shows a perspective view of a differential inductor vertically oriented in a metal stack of a semiconductor package (not shown). This design has offset horizontal sections in metal 1 layer (M1) and metal 18 layer (M18). A vertical section connects the offset horizontal section in metal 1 layer (M1) to an L-shaped horizontal section in metal 2 layer (M2). Another vertical section connects the offset horizontal section in metal 18 layer (M18) to an L-shaped horizontal section in metal 19 layer (M19). The sensor 1725 has an inductor 1724, a sensing membrane 1728 (e.g., nitride passivation layer), and a sensor protective layer 1729 (e.g., a polyimide layer). The ions in a fluid may modulate the charge on the differential inductor 1774 through the sensing membrane 1728. A fluid property measurement circuit 1726 measures a quality factor or inductance of the differential inductor 1774 and outputs a fluid property signal.

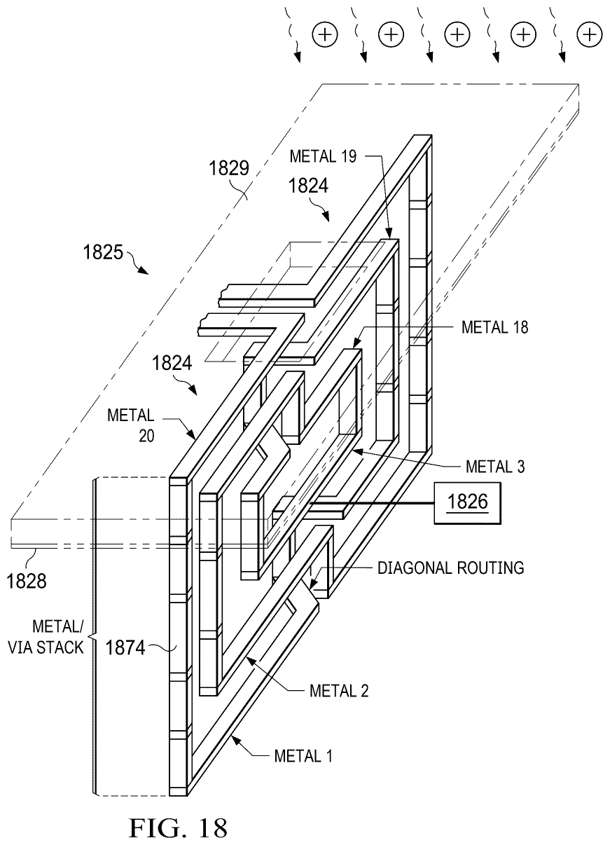

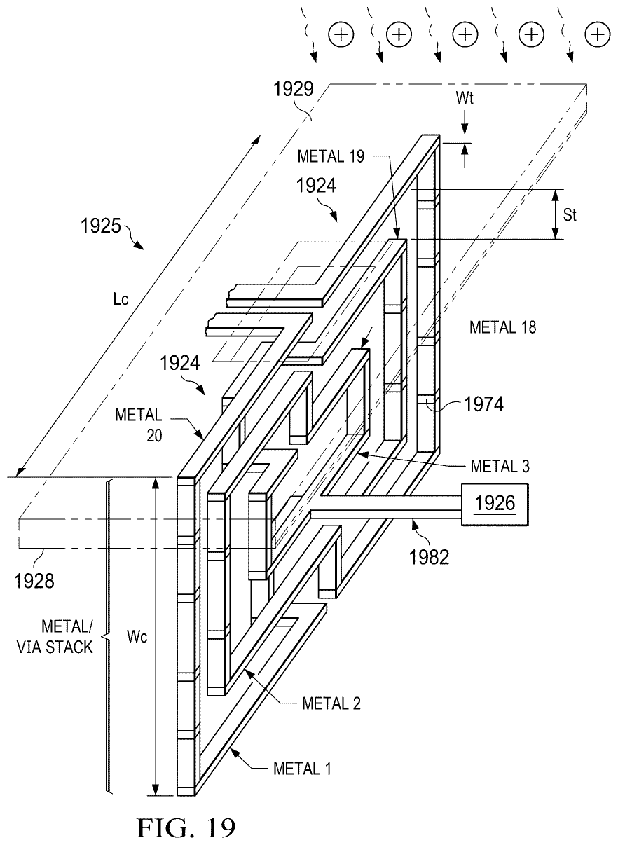

FIG. 18 shows a perspective view of a differential inductor vertically oriented in a metal stack of a semiconductor package (not shown). This design has a diagonal section that connects the horizontal section in metal 1 layer (M1) to an L-shaped horizontal section in metal 2 layer (M2). Another diagonal section connects the horizontal section in metal 18 layer (M18) to an L-shaped horizontal section in metal 19 layer (M19). The sensor 1825 has an inductor 1824, a sensing membrane 1828 (e.g., nitride passivation layer), and a sensor protective layer 1829 (e.g., a polyimide layer). The ions in a fluid may modulate the charge on the differential inductor 1874 through the sensing membrane 1828. A fluid property measurement circuit 1826 measures a quality factor or inductance of the differential inductor 1874 and outputs a fluid property signal.

FIG. 19 shows a perspective view of a differential inductor 1974 vertically oriented in a metal stack of a semiconductor package (not shown). This differential inductor 1974 has a center tap 1982 connected to a horizontal section in metal 3 layer (M3). The sensor 1925 has an inductor 1924, a sensing membrane 1928 (e.g., nitride passivation layer), and a sensor protective layer 1929 (e.g., a polyimide layer). The ions in a fluid may modulate the charge on the differential inductor 1974 through the sensing membrane 1928. A fluid property measurement circuit 1926 is connected to the center tap 1982 and measures a quality factor or inductance of the differential inductor 1974 and outputs a fluid property signal.

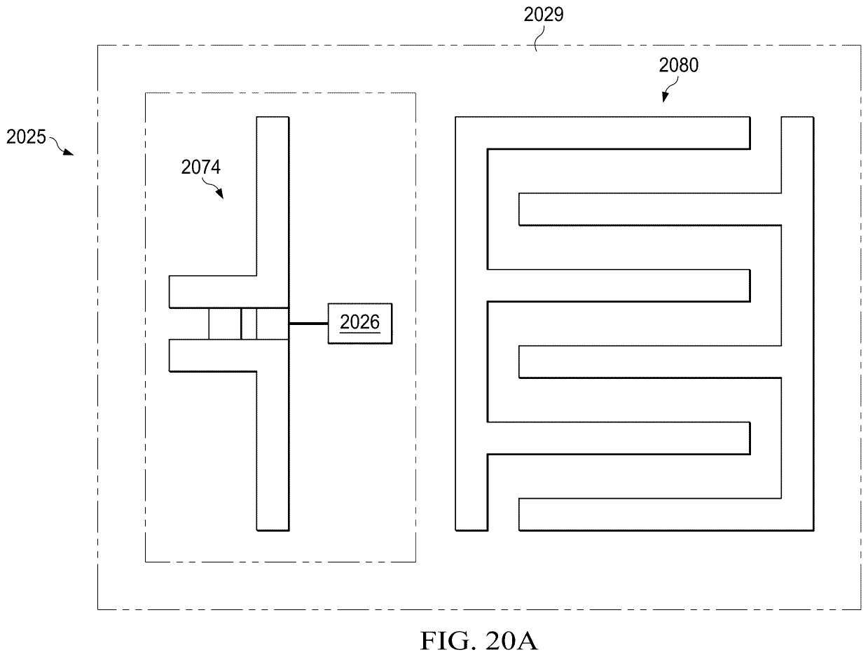

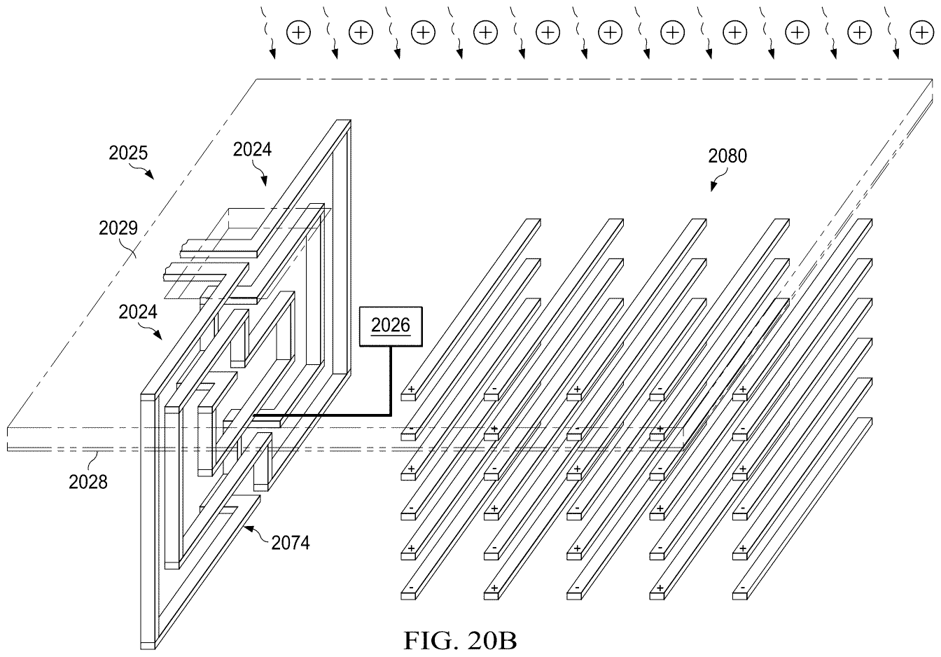

FIGS. 20A and 20B show top and perspective views, respectively, of a high density three-dimensional differential inductor capacitor (LC) tank. The differential inductor 2074 lies in a vertical plane of a complementary metal-oxide-semiconductor (CMOS) metal stack (not shown) and is formed by multiple layers of metal in the metal stack. The MOM capacitor 2080 is three-dimensional and lies in the same complementary metal-oxide-semiconductor (CMOS) metal stack and is formed by multiple layers of metal in the metal stack. The differential inductor 2074 and the MOM capacitor 2080 are formed in the same metal layers of the CMOS metal stack and are offset laterally from one another. The sensor 2025 has an inductor 2024, a sensing membrane 2028 (e.g., nitride passivation layer), and a sensor protective layer 2029 (e.g., a polyimide layer). The ions in a fluid may modulate the charge on the differential inductor 2074 or the MOM capacitor 2080 through the sensing membrane 2028. A fluid property measurement circuit 2026 measures a quality factor or inductance of the differential inductor 2074 or the charge on the MOM capacitor 2080 and outputs a fluid property signal.

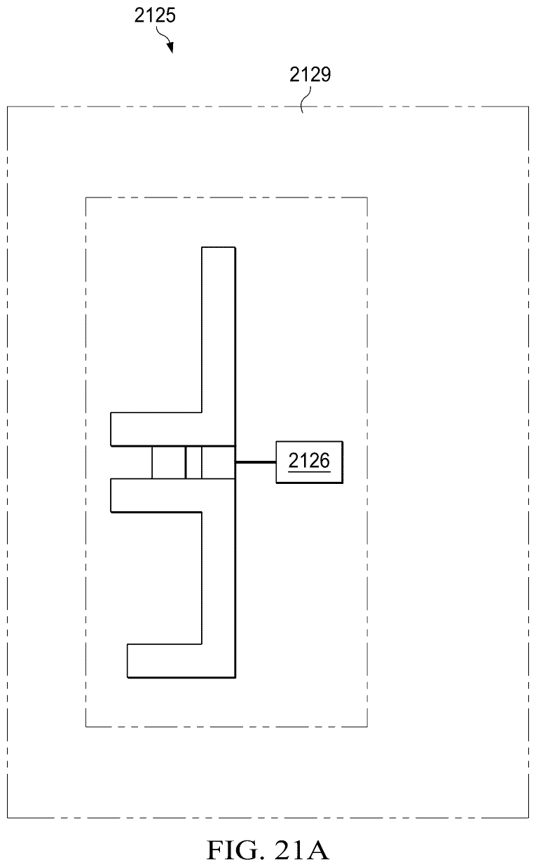

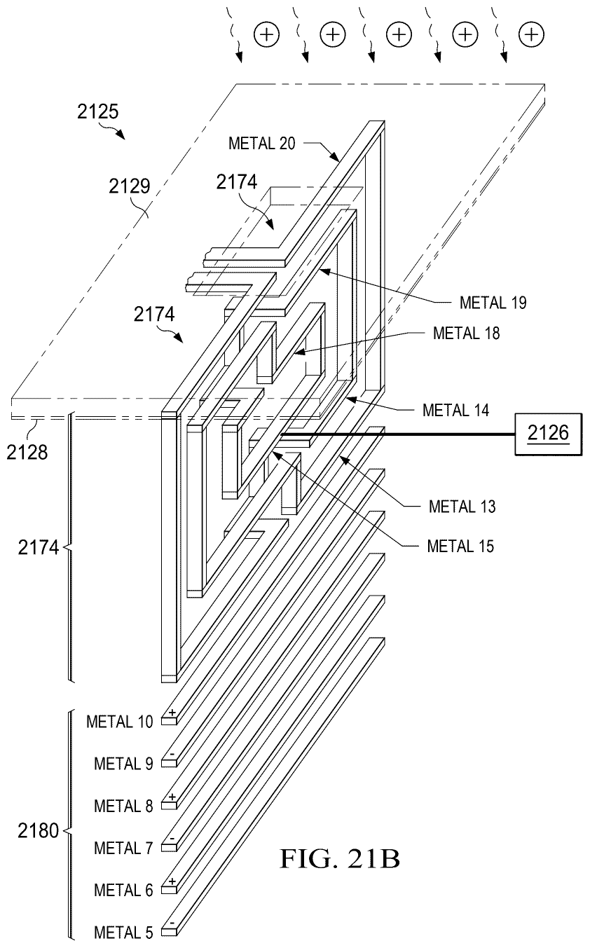

FIGS. 21A and 21B show top and perspective views, respectively, of a high density three-dimensional differential inductor capacitor (LC) tank of the present disclosure, wherein the inductor 2174 and a MOM capacitor 2180 lie in the same vertical plane of a complementary metal-oxide-semiconductor (CMOS) metal stack and are formed by multiple layers of metal in the metal stack. These are vertical components. The MOM capacitor 2180 is formed in metal layers 5 through 10 of the metal stack and the differential inductor 2174 is formed in metal layers 13 through 20 of the same metal stack directly above the MOM capacitor 2180 in the same vertically oriented plane. The differential inductor 2174 may be built with top metals and the MOM capacitor 2180 may be built with bottom metals below a single metal line (or vice versa). The sensor 2125 has a differential inductor 2174, a sensing membrane 2128 (e.g., nitride passivation layer), and a sensor protective layer 2129 (e.g., a polyimide layer). The ions in a fluid may modulate the charge on the differential inductor 2174 or the MOM capacitor 2180 through the sensing membrane 2128. A fluid property measurement circuit 2126 measures a quality factor or inductance of the differential inductor 2174 or the charge on the MOM capacitor 2180 and outputs a fluid property signal.

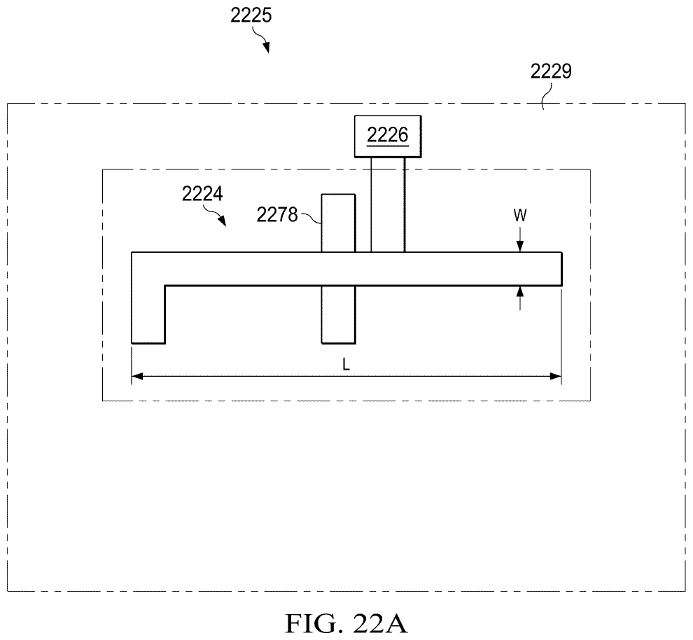

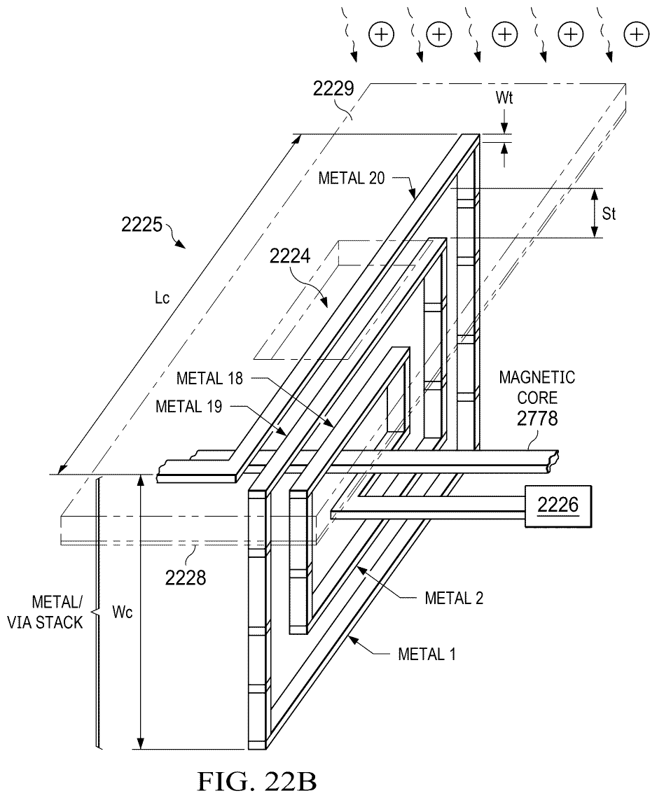

FIGS. 22A and 22B show top and perspective views, respectively, of a vertically oriented inductor 2224 having a magnetic core 2278 through the center of the inductor 2224. The magnetic core 2278 material can be any magnetic material (CoTaZr, Ba3Co2Fe24O41, FeCoXO, FeCoXN, Cr/FeCo/Cr), without limitation. The magnetic material may be integrated into CMOS flow for an integrated inductor 2224 with magnetic core 2278. The magnetic core 2278 can be a single layer or multi layer stacked together. The sensor 2225 has an inductor 2224, a sensing membrane 2228 (e.g., nitride passivation layer), and a sensor protective layer 2229 (e.g., a polyimide layer). The ions in a fluid may modulate the charge on the inductor 2224 or the magnetic core 2278 through the sensing membrane 2228. A fluid property measurement circuit 2226 measures a quality factor or inductance of the inductor 2224 or a charge on the magnetic core 2278 and outputs a fluid property signal.

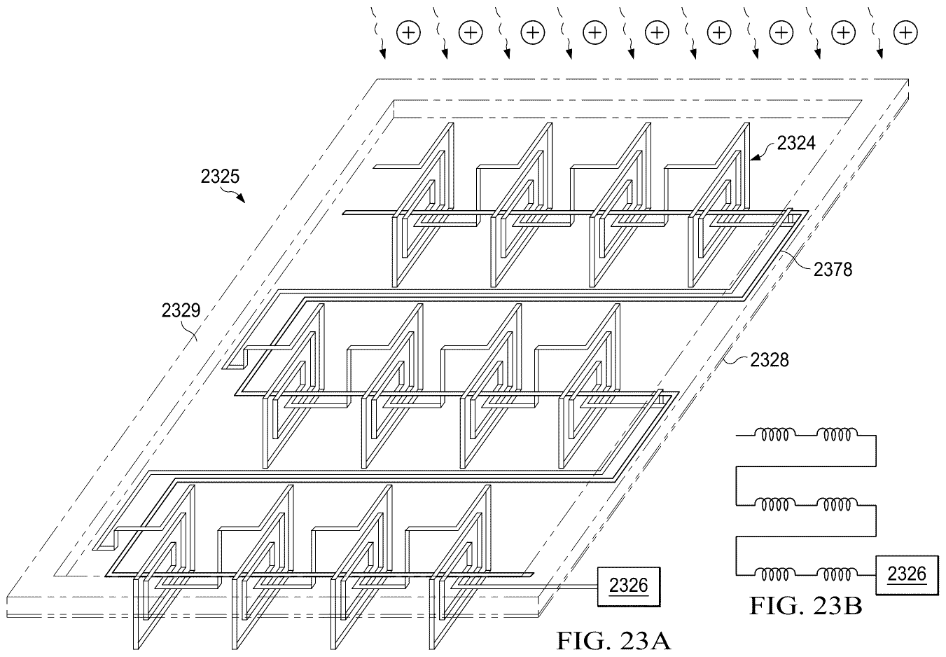

FIG. 23A shows a perspective view of a plurality of vertically oriented high density three-dimensional inductor windings 2324 with a magnetic core 2378, wherein the windings 2324 are laterally offset from one another and are connected in series. The magnetic core 2378 runs through the centers of the inductor windings 2324. In this example, twelve vertically oriented high density three-dimensional inductor windings 2324 are connected in series and the magnetic core 2378 runs through them in the same series. The twelve inductor windings 2324 are oriented in the same or parallel vertically oriented planes and the magnetic core 2378 is horizontally oriented. FIG. 23B shows a schematic representation of the plurality of vertically oriented high density three-dimensional inductor windings 2324 and magnetic core 2378 shown in FIG. 23A. The sensor 2325 has inductor windings 2324, a sensing membrane 2328 (e.g., nitride passivation layer), and a sensor protective layer 2329 (e.g., a polyimide layer). The ions in a fluid may modulate the charge on the inductor 2324 or the magnetic core 2378 through the sensing membrane 2328. A fluid property measurement circuit 2326 measures a quality factor or inductance of the inductor windings 2324 or a charge on the magnetic core 2378 and outputs a fluid property signal.

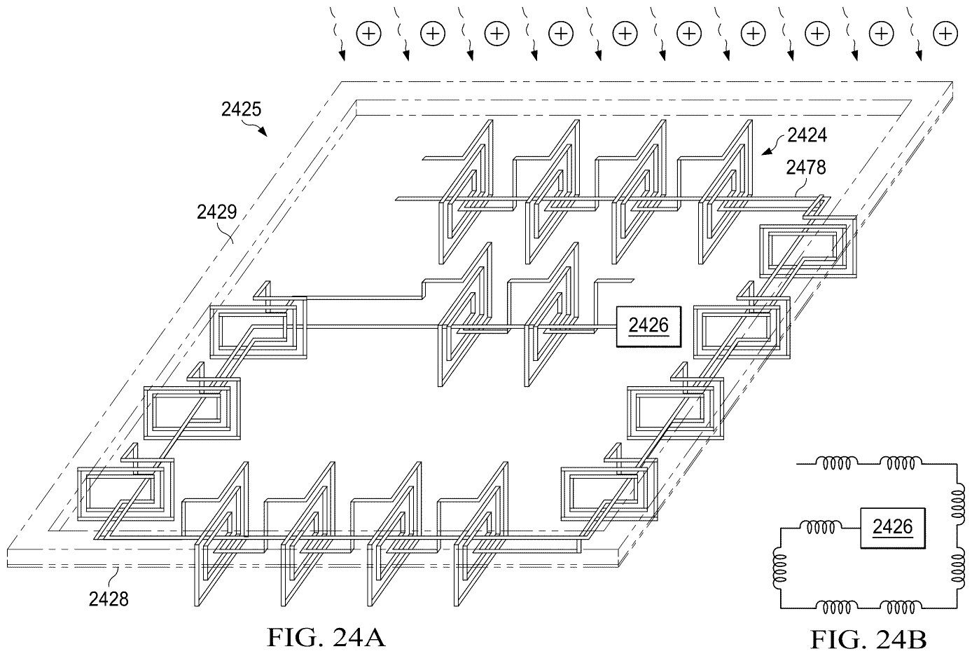

FIG. 24A shows a perspective view of seventeen vertically oriented high density three-dimensional inductor windings and a magnetic core, wherein the windings are laterally offset from one another and are connected in series in a radial or coiled shape within a metal stack. The magnetic core extends through the centers of the inductor windings in a radial or coiled shape within a metal stack. The magnetic core may be in a single layer of the metal stack. In this example, seventeen vertically oriented high density three-dimensional inductor windings are connected in series and the magnetic core extends through them in the same series. Some of the seventeen inductor windings are oriented in the same or parallel planes and others of the seventeen inductor windings are oriented in nonparallel planes. FIG. 24B shows a schematic representation of the plurality of vertically oriented high density three-dimensional inductor windings and magnetic core shown in FIG. 24A. The sensor 2425 has inductor windings 2424, a sensing membrane 2428 (e.g., nitride passivation layer), and a sensor protective layer 2429 (e.g., a polyimide layer). The ions in a fluid may modulate the charge on the inductor 2424 or the magnetic core 2478 through the sensing membrane 2428. A fluid property measurement circuit 2426 measures a quality factor or inductance of the inductor windings 2424 or a charge on the magnetic core 2478 and outputs a fluid property signal.

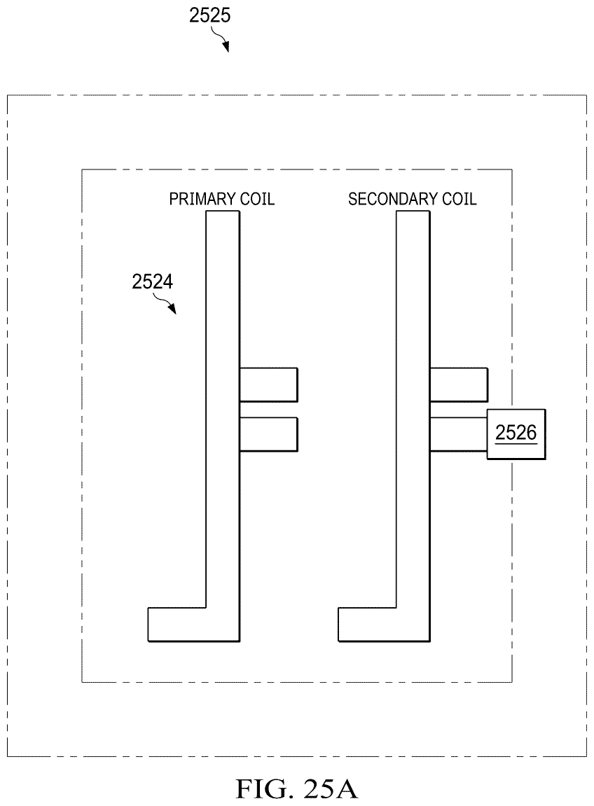

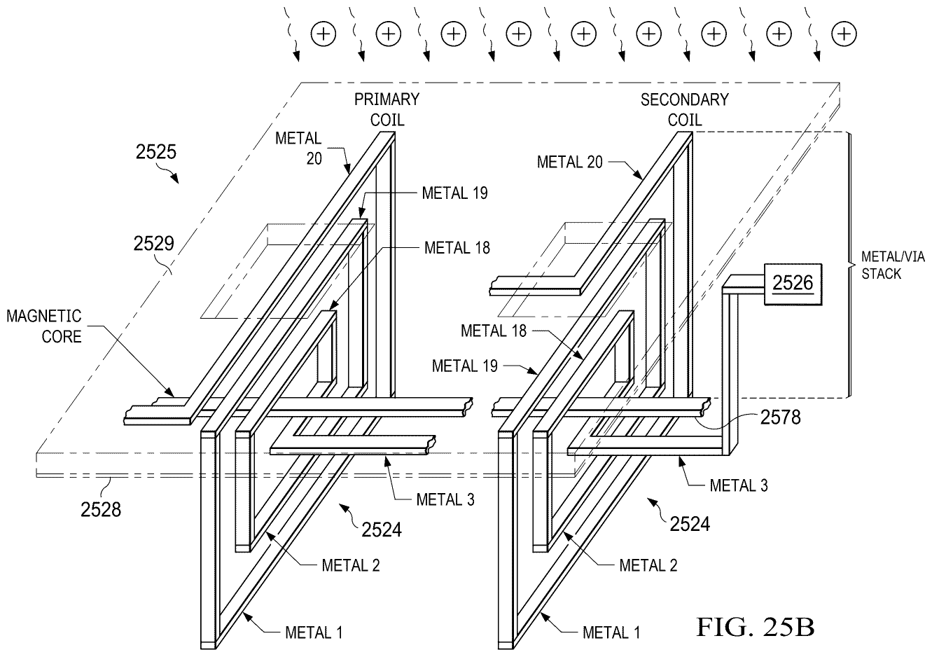

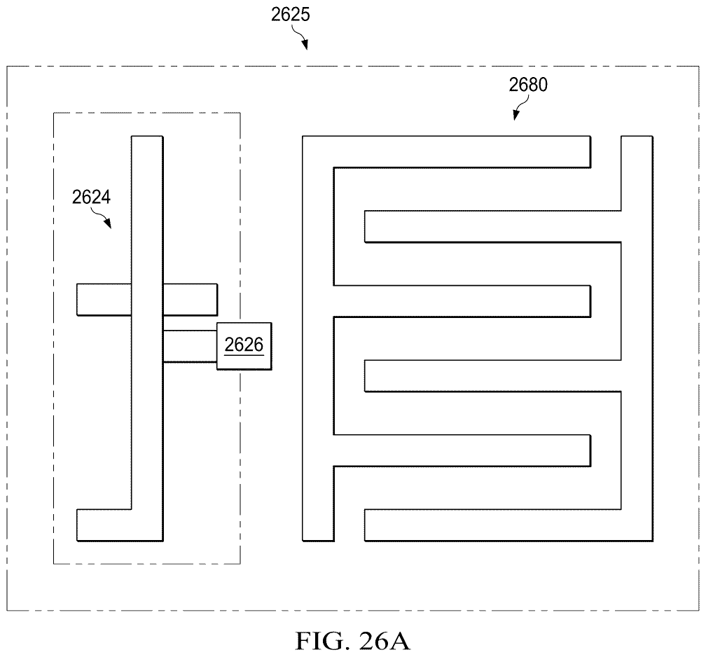

FIGS. 25A and 25B show top and perspective views, respectively, of a high density three-dimensional transformer/Balun with a magnetic core, wherein a primary coil and a secondary coil are formed in the same metal and via layers of a CMOS metal stack and are offset laterally from one another. The magnetic core extends through a single layer of the metal stack. The primary and secondary coils are vertically oriented in a complementary metal-oxide-semiconductor (CMOS) metal stack and are formed by multiple layers of metal in the metal stack. These are vertically oriented windings. The magnetic core extends horizontally oriented through a layer of the metal stack. The sensor 2525 has an inductor 2524, a sensing membrane 2528 (e.g., nitride passivation layer), and a sensor protective layer 2529 (e.g., a polyimide layer). The ions in a fluid may modulate the charge on the inductor 2524 or the magnetic core 2578 through the sensing membrane 2528. A fluid property measurement circuit 2526 measures a quality factor or inductance of the inductor 2524 or a charge on the magnetic core 2578 and outputs a fluid property signal.

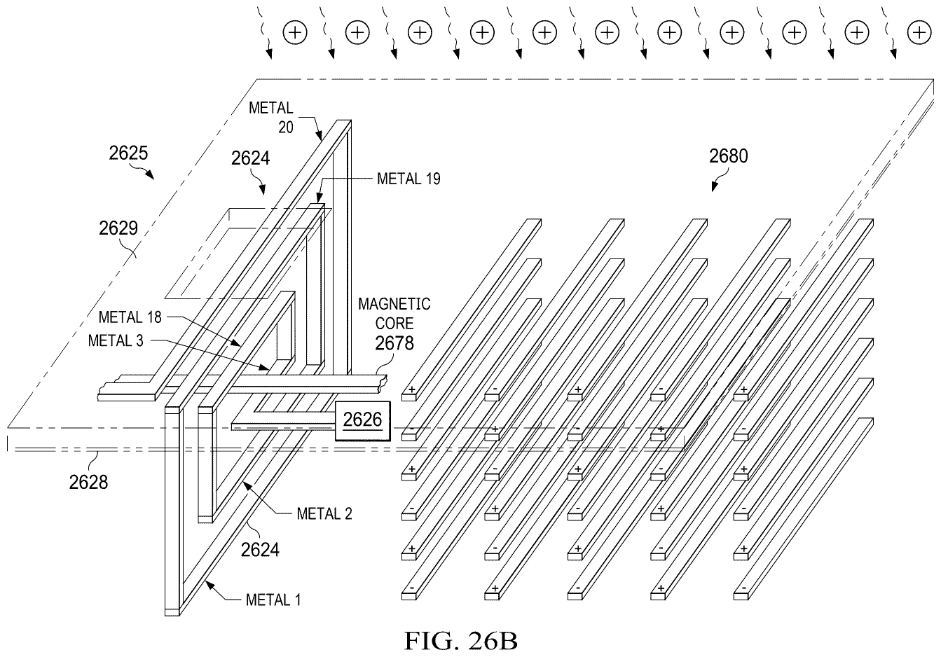

FIGS. 26A and 26B show top and perspective views, respectively, of a high density three-dimensional inductor capacitor (LC) tank having a magnetic core in the inductor. The inductor 2624 lies in a vertical plane of a complementary metal-oxide-semiconductor (CMOS) metal stack and is formed by multiple layers of metal in the metal stack. The magnetic core may extend horizontally oriented in a layer of the metal stack. The MOM capacitor 2680 is three-dimensional and lies in the same complementary metal-oxide-semiconductor (CMOS) metal stack and is formed by multiple layers of metal in the metal stack. The inductor 2624 and the MOM capacitor 2680 are formed in the same metal layers of the CMOS metal stack and are offset laterally from one another. These are vertically oriented components, but the magnetic core is horizontally oriented. The sensor 2625 has an inductor 2624, a sensing membrane 2628 (e.g., nitride passivation layer), and a sensor protective layer 2629 (e.g., a polyimide layer). The ions in a fluid may modulate the charge on the inductor 2624, the magnetic core 2678, or the MOM capacitor 2680 through the sensing membrane 2628. A fluid property measurement circuit 2626 measures a quality factor or inductance of the inductor 2624 or a charge on the magnetic core 2678 or the MOM capacitor 2680 and outputs a fluid property signal.

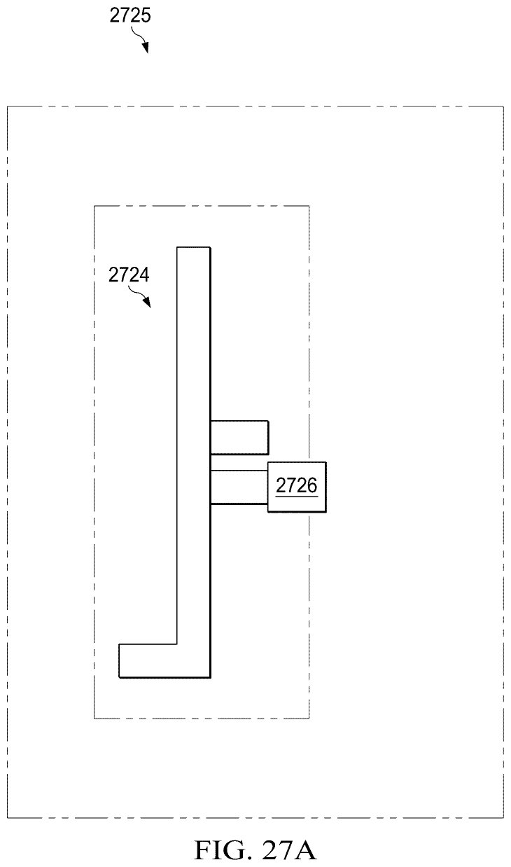

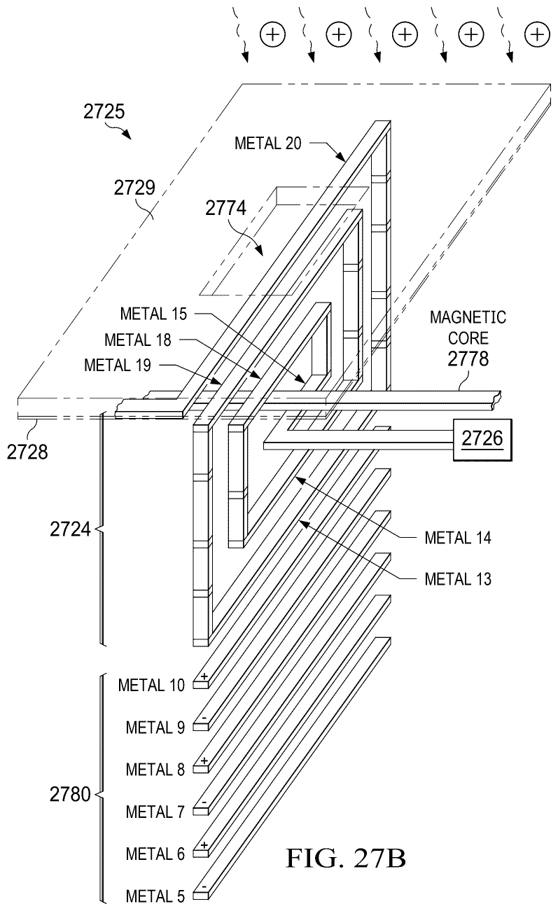

FIGS. 27A and 27B show top and perspective views, respectively, of a high density three-dimensional inductor capacitor (LC) tank of the present disclosure, wherein the inductor 2724 and a MOM capacitor 2780 lie in the same vertical plane of a complementary metal-oxide-semiconductor (CMOS) metal stack and are formed by multiple layers of metal in the metal stack. These are vertical components. The inductor 2724 has a magnetic core extending horizontally oriented through the center of the inductor 2724. The MOM capacitor 2780 is formed in metal layers 5 through 10 of the metal stack. The inductor 2724 is formed in metal layers 13 through 20 of the same metal stack directly above the MOM capacitor 2780 in the same vertically oriented plane. The magnetic core may be formed in metal layer 16 or 17, or a combination of layers 16 and 17. The magnetic core is created at the center of the 3D vertical coil using magnetic material. The inductor 2724 may be built with top metals and the MOM capacitor 2780 may be built with bottom metals below a single metal line (or vice versa). The sensor 2725 has an inductor 2724, a sensing membrane 2728 (e.g., nitride passivation layer), and a sensor protective layer 2729 (e.g., a polyimide layer). The ions in a fluid may modulate the charge on the inductor 2724, the magnetic core 2778, or the MOM capacitor 2780 through the sensing membrane 2728. A fluid property measurement circuit 2726 measures a quality factor or inductance of the inductor 2724 or a charge on the magnetic core 2778 or the MOM capacitor 2780 and outputs a fluid property signal.

Although examples have been described above, other variations and examples may be made from this disclosure without departing from the spirit and scope of these disclosed examples.

What is claimed is:

1. A device comprising:
a semiconductor chip comprising a substrate and an integrated circuit;
a metal stack comprising a plurality of metal layers, wherein the metal stack is connected to the semiconductor chip; and
a first planar spiral differential inductor comprising at least two metal layers of the metal stack, wherein the semiconductor chip defines a semiconductor plane having a semiconductor plane normal vector and the first planar spiral differential inductor defines a first inductor plane having a first inductor plane normal vector, wherein an angle between the semiconductor plane normal vector and the first inductor plane normal vector is between 1 and 90 degrees;
a sensing membrane when interacting with an ionized fluid is operable to attract ions, wherein the sensing membrane is operable to electrically communicate with the first planar spiral differential inductor; and
a fluid property measurement circuit operable to measure a quality factor or inductance of the first planar spiral differential inductor and output a fluid property signal.

2. The device of claim 1, wherein an angle between the semiconductor plane normal vector and the first inductor plane normal vector is 90 degrees.

3. The device of claim 1, comprising: a second planar spiral differential inductor comprising at least two metal layers of the metal stack.

4. The device of claim 3, wherein the first planar spiral differential inductor defines a first plane and second planar spiral differential inductor defines a second plane, wherein the first and second planes are substantially parallel.

5. The device of claim 3, wherein the first planar spiral differential inductor is a primary coil of a transformer and the second planar spiral differential inductor is a secondary coil of the transformer, wherein the fluid property measurement circuit is operable to measure a characteristic of the transformer and output a fluid property signal.

6. The device of claim 1, comprising a MOM capacitor formed in the metal stack and connected with the first planar spiral differential inductor, wherein the MOM capacitor and the first planar spiral differential inductor comprise an inductor capacitor tank.

7. The device of claim 6, wherein the fluid property measurement circuit is operable to measure a characteristic of the inductor capacitor tank and output a fluid property signal.

8. The device of claim 1, wherein the sensing membrane is operable to be sensitive to any ion type or a specific ion type in the ionized fluid.

9. The device of claim 6, wherein the MOM capacitor defines a MOM capacitor plane and the first planar spiral differential inductor defines a first inductor plane, wherein the MOM capacitor plane and the first planar spiral differential inductor plane are the same plane.

10. A method, comprising:
sensing an ionized fluid via a first sensing membrane interacting with a first planar spiral differential inductor;
charging the first planar spiral differential inductor via the first sensing membrane based on the sensing an ionized fluid, wherein the first planar spiral differential inductor comprises a planar spiral inductor comprising at least two metal layers of a metal stack connected to a semiconductor chip comprising a substrate and an integrated circuit, wherein the semiconductor chip defines a semiconductor plane having a semiconductor plane normal vector and the first planar spiral differential inductor defines a first inductor plane having a first inductor plane normal vector, wherein an angle between the semiconductor plane normal vector and the first inductor plane normal vector is between 1 and 90 degrees;
measuring a change in quality factor or inductance of the first planar spiral differential inductor; and
outputting a fluid property signal corresponding to the measured change in quality factor or inductance of the first planar spiral differential inductor.

11. The method of claim 10, wherein sensing an ionized fluid via a sensing membrane comprises sensing a specific ion type.

12. The method of claim 10, comprising:
insulating a second reference planar spiral differential inductor from the ionized fluid;
measuring the quality factor or inductance of second reference planar spiral differential inductor; and
comparing the measured quality factor or inductance of the second reference planar spiral differential inductor with the measured quality factor or inductance of the first spiral planar differential inductor.

13. The method of claim 10, wherein sensing an ionized fluid via a sensing membrane comprises sensing any ion type.

14. The method of claim 10, comprising:
sensing an ionized fluid via a second sensing membrane interacting with a second planar spiral differential inductor;
charging the second planar spiral differential inductor via the second sensing membrane based on the sensing an ionized fluid, wherein the second planar spiral differential inductor comprises a planar spiral differential inductor in the metal stack;
measuring a change in quality factor or inductance of the first and second planar spiral differential inductors; and
outputting a fluid property signal corresponding to the measured change in quality factor or inductance of the first or second planar spiral differential inductors.

15. The method of claim 10, comprising:
charging a MOM capacitor in the metal stack based on the sensing an ionized fluid, wherein the MOM capacitor and the first planar spiral differential inductor comprise an inductor capacitor tank;
wherein measuring a change in quality factor or inductance of the first planar spiral differential inductor comprises measuring a change in a characteristic of the inductor capacitor tank; and
outputting a fluid property signal corresponding to the measured change in the characteristic of the inductor capacitor tank.

16. A fluid property sensor semiconductor device comprising a planar spiral differential inductor in a metal stack, and made by a process, the process comprising:
forming a metal stack on a semiconductor chip, wherein the metal stack comprises a plurality of metal layers, wherein the semiconductor chip comprising a substrate and an integrated circuit;
forming a first planar spiral differential inductor in the metal stack, wherein the first planar spiral differential inductor comprises at least two metal layers of the metal stack, wherein the semiconductor chip defines a semiconductor plane having a semiconductor plane normal vector and the first planar spiral differential inductor defines a first inductor plane having a first inductor plane normal vector, wherein an angle between the semiconductor plane normal vector and the first inductor plane normal vector is between 1 and 90 degrees;
configuring a sensing membrane to electrically communicate with the first planar spiral differential inductor when exposed to an ionized fluid; and
configuring a fluid property measurement circuit to measure a quality factor or inductance of the first planar spiral differential inductor and output a fluid property signal.

17. A fluid property sensor semiconductor device comprising a planar spiral differential inductor in a metal stack, and made by the process of claim 16, comprising: forming a second planar spiral differential inductor in the metal stack, wherein the second planar spiral differential inductor comprises at least two metal layers of the metal stack.

18. A fluid property sensor semiconductor device comprising a planar spiral differential inductor in a metal stack, and made by the process of claim 17, comprising forming a transformer in the metal stack, wherein the first planar spiral differential inductor is a primary coil of the transformer and the second planar spiral differential inductor is a secondary coil of the transformer.

19. A fluid property sensor semiconductor device comprising a planar spiral differential inductor in a metal stack, and made by the process of claim 17, comprising:
insulating the second planar spiral differential inductor from the ionized fluid so the second planar spiral differential inductor is a reference inductor.

20. A fluid property sensor semiconductor device comprising a planar spiral differential inductor in a metal stack, and made by the process of claim 16, comprising:
forming a MOM capacitor in the metal stack;
connecting the first planar spiral differential inductor and the MOM capacitor; and
forming a planar spiral inductor capacitor tank comprising the MOM capacitor and the first planar spiral differential inductor.
